(19) United States
(12) Patent Application Publication
(10) Pub. No.: US 2025/0055481 A1
(43) Pub. Date: Feb. 13, 2025

(54) LIFTING SCHEMES FOR LOW-DENSITY PARITY-CHECK CODES

(71) Applicant: QUALCOMM Incorporated, San Diego, CA (US)

(72) Inventors: Wei YANG, San Diego, CA (US); Pinar SEN, San Diego, CA (US); Jing JIANG, San Diego, CA (US); Gabi SARKIS, San Diego, CA (US); Thomas Joseph RICHARDSON, South Orange, NJ (US)

(21) Appl. No.: 18/448,316

(22) Filed: Aug. 11, 2023

(51) Int. Cl. H03M 13/11

(52) U.S. Cl. CPC H03M 13/1131; H03M 13/1122

(57) ABSTRACT

Methods, systems, and devices for wireless communications are described. A wireless communication device may implement a low-density parity-check (LDPC) code to encode and/or decode bits of a signal. The LDPC code may be defined by a base graph and a lifting scheme. The base graph may include check nodes and variable nodes. The lifting scheme may define a quantity of copies of the base graph used to generate the LDPC code and respective cyclic shifts associated with connected variable nodes and check nodes. The respective cycle shifts may be defined such that one or more cycles associated with a minimum length of the LDPC code are associated with a restriction on second degree variable nodes, nodes associated with least significant bits, or a combination thereof. Additionally, or alternatively, the respective cycle shifts may be defined such that a weighted girth of the LDPC code satisfies a threshold.

### TECHNICAL FIELD

The following relates to wireless communications, including lifting schemes for low-density parity-check (LDPC) codes.

### DESCRIPTION OF THE RELATED TECHNOLOGY

Wireless communications systems are widely deployed to provide various types of communication content such as voice, video, packet data, messaging, broadcast, and so on. These systems may be capable of supporting communication with multiple users by sharing the available system resources (for example, time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM). A wireless multiple-access communications system may include one or more base stations, each supporting wireless communication for communication devices, which may be known as user equipment (UE).

Wireless communication devices, such as UEs and network entities, may implement low-density parity-check (LDPC) codes to encode and decode wireless communications. LDPC encoding and decoding processes are computationally complex, and the amount of hardware involved in encoding or decoding wireless communications using LDPC codes may be directly correlated with the throughput of the wireless communications. The complexity and energy consumption of transmitter and receiver hardware associated with LDPC coding can be a bottleneck in the abilities of wireless communication devices to meet the ever increasing demand for throughput. Thus, updated LDPC coding schemes that support throughput scaling with reduced complexity may be desired.

### SUMMARY

The systems, methods and devices of this disclosure each have several innovative aspects, no single one of which is solely responsible for the desirable attributes disclosed herein.

One innovative aspect of the subject matter described in this disclosure can be implemented in a method for wireless communication by a transmitting device. The method may include encoding a set of bits in accordance with a low-density parity-check (LDPC) code associated with a base graph and a lifting scheme, where the base graph includes a set of multiple of check nodes and a set of multiple of variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the set of bits, or a combination thereof. The method may further include transmitting a signal including the encoded set of bits.

Another innovative aspect of the subject matter described in this disclosure can be implemented in a transmitting device. The transmitting device may include a processing system that includes processor circuitry and memory circuitry that stores code. The processing system may be configured to cause the transmitting device to encode a set of bits in accordance with a LDPC code associated with a base graph and a lifting scheme, where the base graph includes a set of multiple of check nodes and a set of multiple of variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the set of bits, or a combination thereof. The processing system may be further configured to cause the transmitting device to transmit a signal including the encoded set of bits.

Another innovative aspect of the subject matter described in this disclosure can be implemented in a transmitting device. The transmitting device may include means for encoding a set of bits in accordance with a LDPC code associated with a base graph and a lifting scheme, where the base graph includes a set of multiple of check nodes and a set of multiple of variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the set of bits, or a combination thereof. The transmitting may further include means for transmitting a signal including the encoded set of bits.

Another innovative aspect of the subject matter described in this disclosure can be implemented in a non-transitory computer-readable medium storing code for wireless communication. The code may include instructions executable by one or more processors to encode a set of bits in accordance with a LDPC code associated with a base graph and a lifting scheme, where the base graph includes a set of multiple of check nodes and a set of multiple of variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the set of bits, or a combination thereof. The code may further include instructions executable by one or more processors to transmit a signal including the encoded set of bits.

Another innovative aspect of the subject matter described in this disclosure can be implemented in a method for wireless communication by a receiving device. The method may include receiving a signal including an encoded set of bits and decoding the encoded set of bits in accordance with a LDPC code associated with a base graph and a lifting scheme, where the base graph includes a set of multiple of check nodes and a set of multiple of variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the encoded set of bits, or a combination thereof.

Another innovative aspect of the subject matter described in this disclosure can be implemented in a receiving device. The receiving device may include a processing system that includes processor circuitry and memory circuitry that stores code. The processing system may be configured to cause the receiving device to receive a signal including an encoded set of bits and decode the encoded set of bits in accordance with a LDPC code associated with a base graph and a lifting scheme, where the base graph includes a set of multiple of check nodes and a set of multiple of variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the encoded set of bits, or a combination thereof.

Another innovative aspect of the subject matter described in this disclosure can be implemented in a receiving device. The receiving device may include means for receiving a signal including an encoded set of bits and means for decoding the encoded set of bits in accordance with a LDPC code associated with a base graph and a lifting scheme, where the base graph includes a set of multiple of check nodes and a set of multiple of variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the encoded set of bits, or a combination thereof.

Another innovative aspect of the subject matter described in this disclosure can be implemented in a non-transitory computer-readable medium storing code for wireless communication. The code may include instructions executable by one or more processors to receive a signal including an encoded set of bits and decode the encoded set of bits in accordance with a LDPC code associated with a base graph and a lifting scheme, where the base graph includes a set of multiple of check nodes and a set of multiple of variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the encoded set of bits, or a combination thereof.

Another innovative aspect of the subject matter described in this disclosure can be implemented in a method for wireless communication by a transmitting device. The method may include encoding a set of bits in accordance with a LDPC code associated with a base graph and a lifting scheme, where the base graph includes a set of multiple variable nodes and a set of multiple check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes. The method may further include transmitting a signal including the encoded set of bits.

Another innovative aspect of the subject matter described in this disclosure can be implemented in a transmitting device. The transmitting device may include a processing system that includes processor circuitry and memory circuitry that stores code. The processing system may be configured to cause the transmitting device to encode a set of bits in accordance with a LDPC code associated with a base graph and a lifting scheme, where the base graph includes a set of multiple variable nodes and a set of multiple check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes. The processing system may be further configured to cause the transmitting device to transmit a signal including the encoded set of bits.

Another innovative aspect of the subject matter described in this disclosure can be implemented in a transmitting device. The transmitting device may include means for encoding a set of bits in accordance with a LDPC code associated with a base graph and a lifting scheme, where the base graph includes a set of multiple variable nodes and a set of multiple check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes. The transmitting may further include means for transmitting a signal including the encoded set of bits.

Another innovative aspect of the subject matter described in this disclosure can be implemented in a non-transitory computer-readable medium storing code for wireless communication. The code may include instructions executable by one or more processors to encode a set of bits in accordance with a LDPC code associated with a base graph and a lifting scheme, where the base graph includes a set of multiple variable nodes and a set of multiple check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes. The code may further include instructions executable by one or more processors to transmit a signal including the encoded set of bits.

Another innovative aspect of the subject matter described in this disclosure can be implemented in a method for wireless communication by a receiving device. The method may include receiving a signal including an encoded set of bits and decoding the encoded set of bits in accordance with a LDPC code associated with a base graph and a lifting scheme, where the base graph includes a set of multiple variable nodes and a set of multiple check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes.

Another innovative aspect of the subject matter described in this disclosure can be implemented in a receiving device. The receiving device may include a processing system that includes processor circuitry and memory circuitry that stores code. The processing system may be configured to cause the receiving device to receive a signal including an encoded set of bits and decode the encoded set of bits in accordance with a LDPC code associated with a base graph and a lifting scheme, where the base graph includes a set of multiple variable nodes and a set of multiple check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes.

Another innovative aspect of the subject matter described in this disclosure can be implemented in a receiving device. The receiving device may include means for receiving a signal including an encoded set of bits and means for decoding the encoded set of bits in accordance with a LDPC code associated with a base graph and a lifting scheme, where the base graph includes a set of multiple variable nodes and a set of multiple check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes.

Another innovative aspect of the subject matter described in this disclosure can be implemented in a non-transitory computer-readable medium storing code for wireless communication. The code may include instructions executable by one or more processors to receive a signal including an encoded set of bits and decode the encoded set of bits in accordance with a LDPC code associated with a base graph and a lifting scheme, where the base graph includes a set of multiple variable nodes and a set of multiple check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes.

### BRIEF DESCRIPTION OF THE DRAWINGS

FIGS. 1 and 2 show pictorial diagrams of example wireless communications systems that support lifting schemes for low-density parity-check (LDPC) codes.

FIG. 3 shows a lifting diagram of an example lifting scheme for LDPC codes.

FIGS. 4 and 5 show cycle diagrams of example lifting schemes for LDPC codes.

FIG. 6 shows an example process flow that supports lifting schemes for LDPC codes.

FIGS. 7 and 8 show block diagrams of example wireless communications devices that support lifting schemes for LDPC codes.

FIG. 9 shows a block diagram of an example communications manager that supports lifting schemes for LDPC codes.

FIG. 10 shows a block diagram of an example system including a wireless communications device that supports lifting schemes for LDPC codes.

FIG. 11 shows a block diagram of an example system including a wireless communications device that supports lifting schemes for LDPC codes.

FIGS. 12 through 15 show flowcharts illustrating example methods that support lifting schemes for LDPC codes.

### DETAILED DESCRIPTION

The following description is directed to particular implementations for the purposes of describing innovative aspects of this disclosure. However, a person having ordinary skill in the art will readily recognize that the teachings herein can be applied in a multitude of different ways. The described implementations can be implemented in any device, system or network that is capable of transmitting and receiving radio frequency (RF) signals according to one or more of the Institute of Electrical and Electronics Engineers (IEEE) 802.11 standards, the IEEE 802.15 standards, the Bluetooth® standards as defined by the Bluetooth Special Interest Group (SIG), or the Long Term Evolution (LTE), 3G, 4G or 5G (New Radio (NR)) standards promulgated by the 3rd Generation Partnership Project (3GPP), among others. The described implementations can be implemented in any device, system or network that is capable of transmitting and receiving RF signals according to one or more of the following technologies or techniques: code division multiple access (CDMA), time division multiple access (TDMA), frequency division multiple access (FDMA), orthogonal FDMA (OFDMA), single-carrier FDMA (SC-FDMA), single-user (SU) multiple-input multiple-output (MIMO) and multi-user (MU) MIMO. The described implementations also can be implemented using other wireless communication protocols or RF signals suitable for use in one or more of a wireless personal area network (WPAN), a wireless local area network (WLAN), a wireless wide area network (WWAN), or an internet of things (IoT) network.

Some wireless communications systems may implement error correcting codes to transmit signals over noisy communications channels, such as low-density parity-check (LDPC) codes. LDPC codes may be defined by (for example, described by, represented by) an associated base graph and a lifting scheme. The lifting scheme indicates (for example, defines, is associated with) one or more lifting operations performed on the base graph, such as using a circulant identity matrix, to create a quantity of copies of the base graph. The base graph may be defined by variable nodes (for example, columns in a matrix representation of the base graph) and check nodes (for example, rows in the matrix representation of the base graph). Wireless communication devices may implement modulation schemes to map bits to a modulation constellation (for example, a modulation symbol of a modulation scheme). Modulation schemes may be of various orders, such as lower-order modulation schemes (quadrature phase-shift keying (QPSK) modulation) and higher-order modulation schemes (for example, quadrature amplitude modulation (QAM) modulation). A greater quantity of bits may be mapped to a given modulation symbol if implementing a higher-order modulation scheme relative to a lower-order modulation scheme. For higher-order modulation schemes, coded bits of a modulation symbol may be communicated via different channels with different reliabilities (for example, least significant bits (LSBs) and most significant bits (MSBs) of the same modulation symbol may have different reliabilities). In some examples, cyclic shift values defined by lifting schemes (for example, that indicate how nodes of the base graph are connected between multiple copies of the base graph) may not consider the different reliabilities of different symbol bits, which may result in inefficient coding and reduced reliability of encoded communications. This inefficient coding and reduced reliability may negatively impact error floor performance, especially in higher-order modulation schemes (for example, 16QAM and higher).

Various aspects generally relate to LDPC coding, and more specifically, to lifting schemes for LDPC codes that support higher-order modulation schemes with reduced processing complexity and decoding error rates. For example, a wireless communication device may encode and/or decode a set of bits in accordance with (for example, using) an LDPC code defined by a lifting scheme that exploits the different channel reliabilities of higher-order modulation schemes to improve reliability and error floor performance associated with LDPC codes. In some examples, cyclic shifts defined by the lifting scheme may be defined such that a cycle having a minimum length of the LDPC code (for example, a cycle having a minimum length in the base graph lifted in accordance with the lifting scheme, a shortest cycle in the lifted graph) is associated with one or more restrictions, such as a restriction on second degree variable nodes (for example, variable nodes that correspond to two non-zero check nodes) and/or a restriction on variable nodes and/or check nodes corresponding to least significant bits (for example, least reliable bits) of the modulation scheme. For example, the one or more restrictions may indicate that no second degree variable nodes may be included in the shortest cycle (for example, the minimum length cycle), that no variable node that maps to an LSB may be included in the shortest cycle, and/or that at least one third (or higher) degree variable node may be included in the shortest cycle, among other restrictions described herein. In some examples, the cyclic shifts defined by the lifting scheme may be defined to maximize a weighted girth (for example, a minimum weighted length) of the LDPC code. For example, variable nodes may be assigned a respective weight defined by respective degrees of the variable nodes and/or respective reliabilities to which the variable nodes are mapped. Variable nodes with higher weights may map to more reliable (for example, more significant) bits. In some examples, check nodes may similarly be assigned a respective weight defined by respective degrees of the check nodes and/or respective reliabilities to which the check nodes are mapped. A weighted girth of a cycle may be calculated using (for example, by adding) the weights assigned to the nodes in the cycle (for example, rather than corresponding to a quantity of nodes in the cycle), and the lifting scheme may be designed such that the weighted girth satisfies a defined threshold.

Particular aspects of the subject matter described in this disclosure may be implemented to realize one or more of the following potential advantages. The techniques employed by the described communication devices may provide benefits and enhancements to the operation of the communication devices, including increased throughput, reduced encoding and decoding complexity, improved error floor performance, reduced power consumption, and increased reliability, among other benefits. For example, the inclusion of second degree variable nodes in a lifted graph (for example, a base graph lifted in accordance with a lifting scheme) may result in a sparser LDPC code, which may reduce a complexity of implementing the LDPC code. Such complexity reduction may support higher throughput without increasing a computing capability of a communication device to support the higher throughput. Additionally, power consumption may be reduced relative to other designs due to the reduced computational complexity associated with implementing the LDPC code. Further, the restrictions and/or maximization of weighted girth associated with the lifting schemes described herein may increase reliability and improve error floor performance. For example, the restrictions and/or maximization of weighted girth may prevent the occurrence of cycles in a lifted graph having variable nodes that are only second degree variable nodes, which may be trapping sets (for example, due to the not receiving information outside of the loop) that are associated with relatively lower reliability. Additionally, or alternatively, the restrictions and/or maximization of weighted girth may increase the girth of such cycles and/or ensure that relatively more reliable bits are mapped to variable nodes in such cycles, which may increase a reliability of such cycles and reduce the likelihood of errors. Supporting relatively high-order modulation schemes using these techniques for LDPC coding may increase throughput, reduce signaling overhead, and provide for better power management and spectral efficiency in communications between wireless communication devices.

Aspects of the disclosure are initially described in the context of wireless communications systems. Aspects of the disclosure are additionally described with reference to a lifting diagram, cycle diagrams, and a process flow. Aspects of the disclosure are further illustrated by and described with reference to apparatus diagrams, system diagrams, and flowcharts that relate to lifting schemes for LDPC codes.

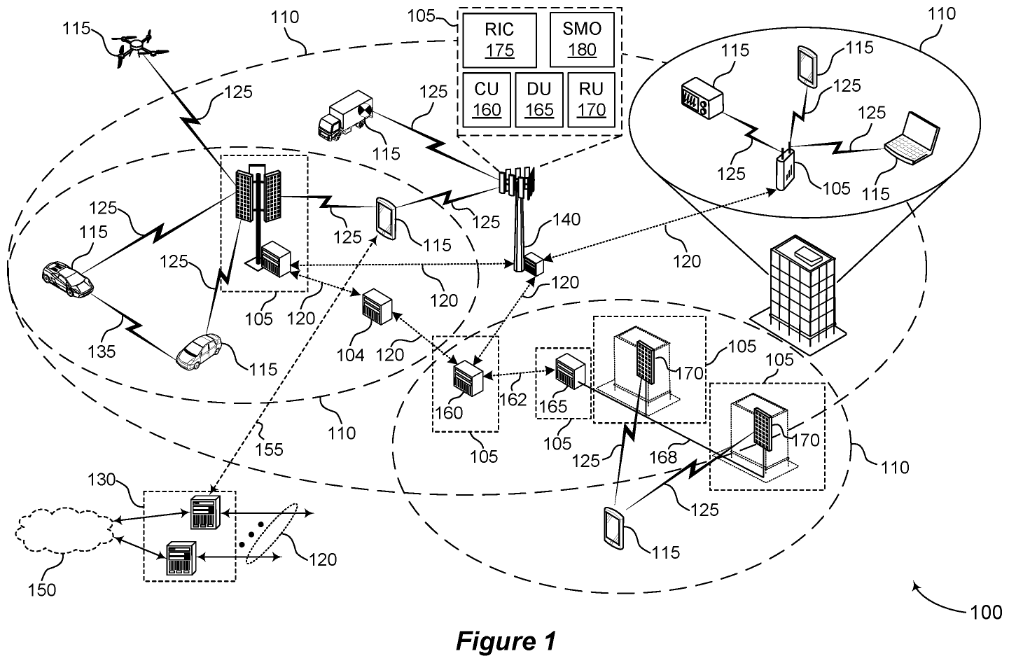

FIG. 1 shows a pictorial diagram of an example wireless communications system 100 that supports lifting schemes for LDPC codes. The wireless communications system 100 may include one or more network entities 105, one or more UEs 115, and a core network 130. In some examples, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some examples, network entities 105 and UEs 115 may wirelessly communicate via one or more communication links 125 (for example, a radio frequency (RF) access link). For example, a network entity 105 may support a coverage area 110 (for example, a geographic coverage area) over which the UEs 115 and the network entity 105 may establish one or more communication links 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices, such as other UEs 115 or network entities 105, as shown in FIG. 1.

As described herein, a node of the wireless communications system 100, which may be referred to as a network node, or a wireless node, may be a network entity 105 (for example, any network entity described herein), a UE 115 (for example, any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, computing system, or the like may include disclosure of the UE 115, network entity 105, apparatus, device, computing system, or the like being a node. For example, disclosure that a UE 115 is configured to receive information from a network entity 105 also discloses that a first node is configured to receive information from a second node.

In some examples, network entities 105 may communicate with the core network 130, or with one another, or both. For example, network entities 105 may communicate with the core network 130 via one or more backhaul communication links 120 (for example, in accordance with an S1, N2, N3, or other interface protocol). In some examples, network entities 105 may communicate with one another via a backhaul communication link 120 (for example, in accordance with an X2, Xn, or other interface protocol) either directly (for example, directly between network entities 105) or indirectly (for example, via a core network 130). In some examples, network entities 105 may communicate with one another via a midhaul communication link 162 (for example, in accordance with a midhaul interface protocol) or a fronthaul communication link 168 (for example, in accordance with a fronthaul interface protocol), or any combination thereof. The backhaul communication links 120, midhaul communication links 162, or fronthaul communication links 168 may be or include one or more wired links (for example, an electrical link, an optical fiber link), one or more wireless links (for example, a radio link, a wireless optical link), among other examples or various combinations thereof. A UE 115 may communicate with the core network 130 via a communication link 155.

One or more of the network entities 105 described herein may include or may be referred to as a base station 140 (for example, a base transceiver station, a radio base station, an NR base station, an access point, a radio transceiver, a NodeB, an eNodeB (eNB), a next-generation NodeB or a giga-NodeB (either of which may be referred to as a gNB), a 5G NB, a next-generation eNB (ng-eNB), a Home NodeB, a Home eNodeB, or other suitable terminology). In some examples, a network entity 105 (for example, a base station 140) may be implemented in an aggregated (for example, monolithic, standalone) base station architecture, which may be configured to utilize a protocol stack that is physically or logically integrated within a single network entity 105 (for example, a single RAN node, such as a base station 140).

In some examples, a network entity 105 may be implemented in a disaggregated architecture (for example, a disaggregated base station architecture, a disaggregated RAN architecture), which may be configured to utilize a protocol stack that is physically or logically distributed among two or more network entities 105, such as an integrated access backhaul (IAB) network, an open RAN (O-RAN) (for example, a network configuration sponsored by the O-RAN Alliance), or a virtualized RAN (vRAN) (for example, a cloud RAN (C-RAN)). For example, a network entity 105 may include one or more of a central unit (CU) 160, a distributed unit (DU) 165, a radio unit (RU) 170, a RAN Intelligent Controller (RIC) 175 (for example, a Near-Real Time RIC (Near-RT RIC), a Non-Real Time RIC (Non-RT RIC)), a Service Management and Orchestration (SMO) 180 system, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (for example, separate physical locations). In some examples, one or more network entities 105 of a disaggregated RAN architecture may be implemented as virtual units (for example, a virtual CU (VCU), a virtual DU (VDU), a virtual RU (VRU)).

The split of functionality between a CU 160, a DU 165, and an RU 170 is flexible and may support different functionalities depending on which functions (for example, network layer functions, protocol layer functions, baseband functions, RF functions, and any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some examples, the CU 160 may host upper protocol layer (for example, layer 3 (L3), layer 2 (L2)) functionality and signaling (for example, Radio Resource Control (RRC), service data adaption protocol (SDAP), Packet Data Convergence Protocol (PDCP)). The CU 160 may be connected to one or more DUs 165 or RUs 170, and the one or more DUs 165 or RUs 170 may host lower protocol layers, such as layer 1 (L1) (for example, physical (PHY) layer) or L2 (for example, radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (for example, via one or more RUs 170). In some cases, a functional split between a CU 160 and a DU 165, or between a DU 165 and an RU 170 may be within a protocol layer (for example, some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to one or more DUs 165 via a midhaul communication link 162 (for example, F1, F1-c. F1-u), and a DU 165 may be connected to one or more RUs 170 via a fronthaul communication link 168 (for example, open fronthaul (FH) interface). In some examples, a midhaul communication link 162 or a fronthaul communication link 168 may be implemented in accordance with an interface (for example, a channel) between layers of a protocol stack supported by respective network entities 105 that are in communication via such communication links.

In wireless communications systems (for example, wireless communications system 100), infrastructure and spectral resources for radio access may support wireless backhaul link capabilities to supplement wired backhaul connections, providing an IAB network architecture (for example, to a core network 130). In some cases, in an IAB network, one or more network entities 105 (for example, IAB nodes 104) may be partially controlled by each other. One or more IAB nodes 104 may be referred to as a donor entity or an IAB donor. One or more DUs 165 or one or more RUs 170 may be partially controlled by one or more CUs 160 associated with a donor network entity 105 (for example, a donor base station 140). The one or more donor network entities 105 (for example, IAB donors) may be in communication with one or more additional network entities 105 (for example, IAB nodes 104) via supported access and backhaul links (for example, backhaul communication links 120). IAB nodes 104 may include an IAB mobile termination (IAB-MT) controlled (for example, scheduled) by DUs 165 of a coupled IAB donor. An IAB-MT may include an independent set of antennas for relay of communications with UEs 115, or may share the same antennas (for example, of an RU 170) of an IAB node 104 used for access via the DU 165 of the IAB node 104 (for example, referred to as virtual IAB-MT (vIAB-MT)). In some examples, the IAB nodes 104 may include DUs 165 that support communication links with additional entities (for example, IAB nodes 104, UEs 115) within the relay chain or configuration of the access network (for example, downstream). In such cases, one or more components of the disaggregated RAN architecture (for example, one or more IAB nodes 104 or components of IAB nodes 104) may be configured to operate according to the techniques described herein.

In the case of the techniques described herein applied in the context of a disaggregated RAN architecture, one or more components of the disaggregated RAN architecture may be configured to support lifting schemes for LDPC codes as described herein. For example, some operations described as being performed by a UE 115 or a network entity 105 (for example, a base station 140) may additionally, or alternatively, be performed by one or more components of the disaggregated RAN architecture (for example, IAB nodes 104, DUs 165, CUs 160, RUs 170, RIC 175, SMO 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a tablet computer, a laptop computer, or a personal computer. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, or vehicles, meters, among other examples.

The UEs 115 described herein may be able to communicate with various types of devices, such as other UEs 115 that may sometimes act as relays as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via one or more communication links 125 (for example, an access link) using resources associated with one or more carriers. The term “carrier” may refer to a set of RF spectrum resources having a defined physical layer structure for supporting the communication links 125. For example, a carrier used for a communication link 125 may include a portion of a RF spectrum band (for example, a bandwidth part (BWP)) that is operated according to one or more physical layer channels for a given radio access technology (for example, LTE, LTE-A, LTE-A Pro, NR). Each physical layer channel may carry acquisition signaling (for example, synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (for example, entity, sub-entity) of a network entity 105. For example, the terms “transmitting,” “receiving,” or “communicating,” when referring to a network entity 105, may refer to any portion of a network entity 105 (for example, a base station 140, a CU 160, a DU 165, a RU 170) of a RAN communicating with another device (for example, directly or via one or more other network entities 105).

The communication links 125 shown in the wireless communications system 100 may include downlink transmissions (for example, forward link transmissions) from a network entity 105 to a UE 115, uplink transmissions (for example, return link transmissions) from a UE 115 to a network entity 105, or both, among other configurations of transmissions. Carriers may carry downlink or uplink communications (for example, in an FDD mode) or may be configured to carry downlink and uplink communications (for example, in a TDD mode).

Signal waveforms transmitted via a carrier may be made up of multiple subcarriers (for example, using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (for example, a duration of one modulation symbol) and one subcarrier, in which case the symbol period and subcarrier spacing may be inversely related. The quantity of bits carried by each resource element may depend on the modulation scheme (for example, the order of the modulation scheme, the coding rate of the modulation scheme, or both), such that a relatively higher quantity of resource elements (for example, in a transmission duration) and a relatively higher order of a modulation scheme may correspond to a relatively higher rate of communication. A wireless communications resource may refer to a combination of an RF spectrum resource, a time resource, and a spatial resource (for example, a spatial layer, a beam), and the use of multiple spatial resources may increase the data rate or data integrity for communications with a UE 115.

The time intervals for the network entities 105 or the UEs 115 may be expressed in multiples of a basic time unit which may, for example, refer to a sampling period of Tₛ=1/(Δfₘₐₓ·N_{f}) seconds, for which Δfₘₐₓ may represent a supported subcarrier spacing, and N_{f} may represent a supported discrete Fourier transform (DFT) size. Time intervals of a communications resource may be organized according to radio frames each having a specified duration (for example, 10 milliseconds (ms)). Each radio frame may be identified by a system frame number (SFN) (for example, ranging from 0 to 1023).

Each frame may include multiple consecutively-numbered subframes or slots, and each subframe or slot may have the same duration. In some examples, a frame may be divided (for example, in the time domain) into subframes, and each subframe may be further divided into a quantity of slots. Alternatively, each frame may include a variable quantity of slots, and the quantity of slots may depend on subcarrier spacing. Each slot may include a quantity of symbol periods (for example, depending on the length of the cyclic prefix prepended to each symbol period). In some wireless communications systems 100, a slot may further be divided into multiple mini-slots associated with one or more symbols. Excluding the cyclic prefix, each symbol period may be associated with one or more (for example, N_{f}) sampling periods. The duration of a symbol period may depend on the subcarrier spacing or frequency band of operation.

A subframe, a slot, a mini-slot, or a symbol may be the smallest scheduling unit (for example, in the time domain) of the wireless communications system 100 and may be referred to as a transmission time interval (TTI). In some examples, the TTI duration (for example, a quantity of symbol periods in a TTI) may be variable. Additionally, or alternatively, the smallest scheduling unit of the wireless communications system 100 may be dynamically selected (for example, in bursts of shortened TTIs (STTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (for example, a control resource set (CORESET)) for a physical control channel may be defined by a set of symbol periods and may extend across the system bandwidth or a subset of the system bandwidth of the carrier. One or more control regions (for example, CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (for example, control channel elements (CCEs)) associated with encoded information for a control information format having a given payload size. Search space sets may include common search space sets configured for sending control information to multiple UEs 115 and UE-specific search space sets for sending control information to a specific UE 115.

In some examples, a network entity 105 (for example, a base station 140, an RU 170) may be movable and therefore provide communication coverage for a moving coverage area 110. In some examples, different coverage areas 110 associated with different technologies may overlap, but the different coverage areas 110 may be supported by the same network entity 105. In some other examples, the overlapping coverage areas 110 associated with different technologies may be supported by different network entities 105. The wireless communications system 100 may include, for example, a heterogeneous network in which different types of the network entities 105 provide coverage for various coverage areas 110 using the same or different radio access technologies.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some examples, a UE 115 may be configured to support communicating directly with other UEs 115 via a device-to-device (D2D) communication link 135 (for example, in accordance with a peer-to-peer (P2P), D2D, or sidelink protocol). In some examples, one or more UEs 115 of a group that are performing D2D communications may be within the coverage area 110 of a network entity 105 (for example, a base station 140, an RU 170), which may support aspects of such D2D communications being configured by (for example, scheduled by) the network entity 105. In some examples, one or more UEs 115 of such a group may be outside the coverage area 110 of a network entity 105 or may be otherwise unable to or not configured to receive transmissions from a network entity 105. In some examples, groups of the UEs 115 communicating via D2D communications may support a one-to-many (1:M) system in which each UE 115 transmits to each of the other UEs 115 in the group. In some examples, a network entity 105 may facilitate the scheduling of resources for D2D communications. In some other examples, D2D communications may be carried out between the UEs 115 without an involvement of a network entity 105.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (for example, a mobility management entity (MME), an access and mobility management function (AMF)) and at least one user plane entity that routes packets or interconnects to external networks (for example, a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (for example, base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (for example, less than 100 kilometers) compared to communications using the smaller frequencies and longer waves of the high frequency (HF) or very high frequency (VHF) portion of the spectrum below 300 MHz.

The wireless communications system 100 may also operate using a super high frequency (SHF) region, which may be in the range of 3 GHz to 30 GHz, also known as the centimeter band, or using an extremely high frequency (EHF) region of the spectrum (for example, from 30 GHz to 300 GHz), also known as the millimeter band. In some examples, the wireless communications system 100 may support millimeter wave (mmW) communications between the UEs 115 and the network entities 105 (for example, base stations 140, RUs 170), and EHF antennas of the respective devices may be smaller and more closely spaced than UHF antennas. In some examples, such techniques may facilitate using antenna arrays within a device. The propagation of EHF transmissions, however, may be subject to even greater attenuation and shorter range than SHF or UHF transmissions. The techniques disclosed herein may be employed across transmissions that use one or more different frequency regions, and designated use of bands across these frequency regions may differ by country or regulating body.

The wireless communications system 100 may utilize both licensed and unlicensed RF spectrum bands. For example, the wireless communications system 100 may employ License Assisted Access (LAA), LTE-Unlicensed (LTE-U) radio access technology, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some examples, operations using unlicensed bands may be based on a carrier aggregation configuration in conjunction with component carriers operating using a licensed band (for example, LAA). Operations using unlicensed spectrum may include downlink transmissions, uplink transmissions, P2P transmissions, or D2D transmissions, among other examples.

A network entity 105 (for example, a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

Beamforming, which may also be referred to as spatial filtering, directional transmission, or directional reception, is a signal processing technique that may be used at a transmitting device or a receiving device (for example, a network entity 105, a UE 115) to shape or steer an antenna beam (for example, a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (for example, with respect to the antenna array of the transmitting device or receiving device, or with respect to some other orientation).

The wireless communications system 100 may be a packet-based network that operates according to a layered protocol stack. In the user plane, communications at the bearer or PDCP layer may be IP-based. An RLC layer may perform packet segmentation and reassembly to communicate via logical channels. A MAC layer may perform priority handling and multiplexing of logical channels into transport channels. The MAC layer also may implement error detection techniques, error correction techniques, or both to support retransmissions to improve link efficiency. In the control plane, an RRC layer may provide establishment, configuration, and maintenance of an RRC connection between a UE 115 and a network entity 105 or a core network 130 supporting radio bearers for user plane data. A PHY layer may map transport channels to physical channels.

A transmitting device (for example, a network entity 105, a UE 115) may encode a set of bits using an LDPC code defined by a base graph, which may be defined by variable nodes and check nodes, and a lifting scheme, which may define a quantity of copies of the base graph used to generate the LDPC code and how the base graph and the copies of the base graph are interconnected (for example, by defining cyclic shifts associated with edges of the graphs). A receiving device (for example, a network entity 105, a UE 115) may receive the encoded set of bits and decode the set of bits using the LDPC code. The base graph design may support second degree variable nodes, which may be variable nodes that correspond to (for example, connect to) two non-zero check nodes. In some examples, the base graph design may include more second degree nodes associated with higher significant bits than with lower significant bits (for example, more second degree nodes associated with MSBs or second MSBs than with third MSBs or LSBs. Bits with higher significance may be associated with higher channel reliability, and bits with lower significance may be associated with lower channel reliability.

In accordance with examples described herein, the lifting scheme may be designed to support higher-order modulation in which bits may be associated with varying modulation levels. In some examples, the lifting scheme may be associated with one or more restrictions to improve reliability and error floor performance of an LDPC code defined by the lifting scheme. For example, the lifting scheme may be defined such that cycles having a minimum length of the LDPC code may be restricted such that there are no second degree variable nodes, there is at least one third (or higher) degree variable in the cycles, or that LSBs are excluded from the cycles, or a combination thereof. Such restrictions may support a smaller girth of the LDPC code (for example, an LDPC code with girth six). LDPC codes with relatively smaller girths may have a relatively smaller variable node degree on average, which may reduce encoding and/or decoding complexity of the LDPC code as throughput scales while increasing a reliability associated with the LDPC code.

In some examples, the lifting scheme may be defined to maximize a weighted girth of the LDPC code. For example, each variable node and check node may be assigned (for example, associated with) a weight, and the weighted length of a cycle may be the sum of the weights of nodes included in the cycle. The weighted girth of the LDPC code may be the minimum of the weighted lengths of all cycles of the LDPC code (for example, all cycles of a lifted graph). Weights assigned to variable nodes may be in accordance with a degree of the variable node and/or a reliability of the corresponding bit channel. For example, higher reliabilities and/or higher degrees may correspond to higher weights. As such, variable nodes corresponding to lower significant bits and/or lower-degree variable nodes may be assigned relatively smaller weights, and thus greater importance in designing the lifting scheme for the LDPC code to maximize the weighted girth, which may improve reliability and error floor performance of bits encoded using such an LDPC code.

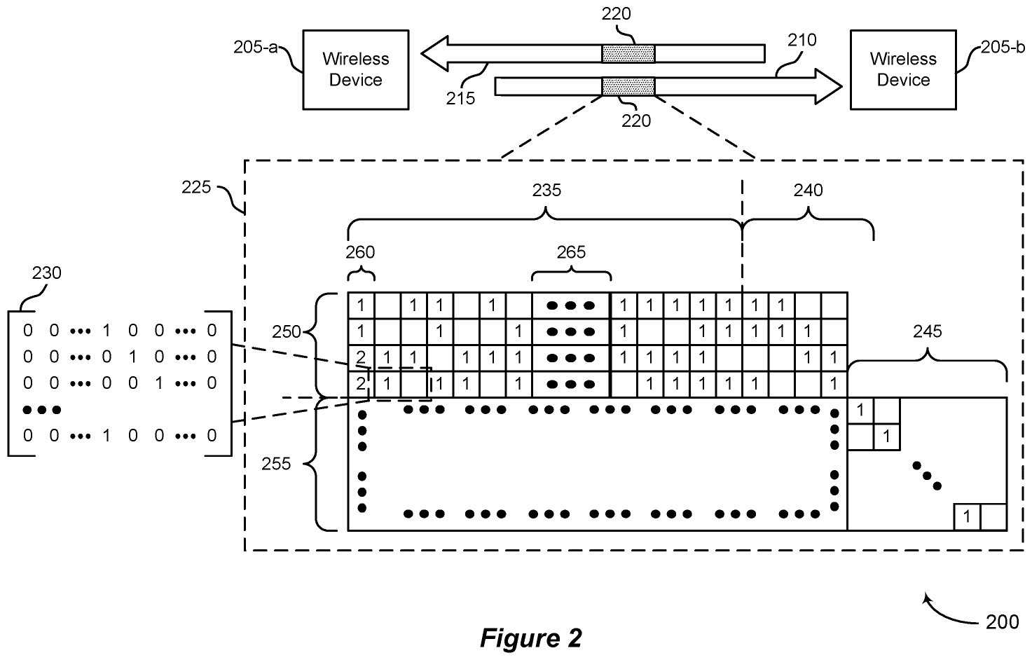

FIG. 2 shows a pictorial example of an example wireless communications system 200 that supports lifting schemes for LDPC codes. The wireless communications system may implement aspects of the wireless communications system 100 or may be implemented by aspects of the wireless communications system 100. For example, the wireless communications system 200 may include a wireless device 205-a and a wireless device 205-b, which may be examples of corresponding devices described herein (for example, a network entity 105, a UE 115). The wireless device 205-a may communicate with the wireless device 205-b via the communication link 210 and the communication link 215. The communication link 210 and the communication link 215 may support uplink or downlink communications and/or in some cases may be a sidelink connection. A device transmitting a signal 220 (for example, a message in the uplink, downlink, or sidelink) may be referred to as a transmitting device, and a device receiving the signal 220 (for example, in the uplink, downlink, or sidelink) may be referred to as a receiving device.

The wireless communications system 200 may implement forward error correction (FEC) to reduce transmission errors when performing communications over unreliable or noisy channels. In some examples, the wireless device 205-a may be a transmitting device and may transmit a signal 220 to the wireless device 205-b, which may be a receiving device, in accordance with an error correction code. For example, the wireless device 205-a may transmit a signal 220 using an LDPC code (such as a quasi-cyclic (QC) LDPC code). The LDPC code may be defined by (for example, described by) a base graph 225 (such as a protograph) and a lifting matrix 230. The base graph 225 may capture (for example, represent, indicate) the macroscopic properties of the LDPC code (for example, a threshold).

In some examples, the base graph 225 may be represented as a matrix (such as a base matrix). The base graph 225 may include multiple columns and multiple rows. Each column of the multiple columns of the base graph 225 may denote (for example, be defined as) a variable node, and each row of the multiple rows of the base graph 225 may denote a check node. In some examples, the multiple variable nodes of the base graph 225 may be further include multiple information nodes 235, multiple core parity nodes 240, multiple extension parity nodes 245, or a combination thereof. In some examples, the multiple check nodes of the base graph 225 may include multiple core check nodes 250 and multiple extension check nodes 255. Each element in the base graph 225 may be a non-negative integer, where ‘0’ indicates there is no connection between the corresponding variable node and check node, ‘1’ indicates that is one edge (for example, one connection) between the corresponding variable node and check node, ‘2’ indicates that there are two edges between the corresponding variable node and check node, and so on. In the example of FIG. 2, a lack of a number in an element of the base graph 225 may indicate a ‘0’ value for the element.

Each variable node may be associated with a degree, which may denote a quantity of check nodes associated with each variable node (for example, a quantity of check nodes that a variable node is connected to in the base graph 225). For example, the degree associated with a variable node may indicate a quantity of edges in the column of the base graph 225 corresponding to the variable node (for example, the sum of the non-zero elements of the column associated with the variable node). In some examples, the multiple information nodes 235 may include one or more special extension check nodes 265. In some examples, the core parity nodes 240 and/or extension parity nodes 245 may be a chain of second degree nodes.

In some examples, a first variable node of the base graph 225 may be a punctured information node 260, which may correspond to a non-transmitted node (for example, a node for which no information is sent), and one or more elements of the first variable node may have a value a ‘2’ or above (for example, the first variable node may include one or more double edged connections). In some other examples, the first and second variable nodes of the base graph 225 may be punctured information nodes 260.

The LDPC code may be further defined by a lifting scheme. The lifting scheme may define lifting matrices 230 (for example, lifting values) corresponding to edges of the base graph 225. In some examples, the lifting scheme may be the collection of all of the lifting matrices 230 corresponding to the edges of the base graph 225. In some examples, a lifting matrix 230 may be a circulant identity matrix, and the wireless device 205-a and/or the wireless device 205-b may lift (for example, perform a lifting operation on) one or more entries of the base graph 225 according to the circulant identity matrix. In some examples, a lifting matrix 230 may be a dual-diagonal lifting matrix (for example, a circulant dual-diagonal lifting matrix). An example of a 4×4 dual-diagonal lifting matrix is as follows:

| | | | |
|---|---|---|---|
| 1 | 0 | 0 | 1 |
| 1 | 1 | 0 | 0 |
| 0 | 1 | 1 | 0 |
| 0 | 0 | 1 | 1 |

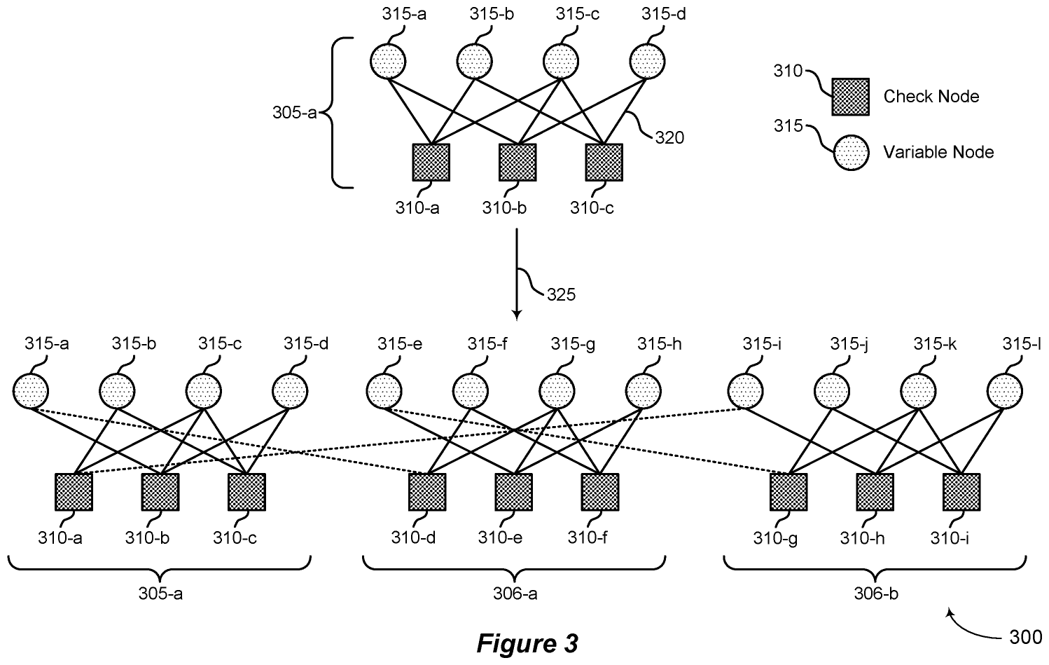

A cyclic shift associated with the circulant identity matrix may be indicated by a non-zero value in the base graph 225. In some examples, each variable node of the base graph 225 may be associated with a quantity of coded bits associated with the LDPC code, and the dimensions of the lifting matrix 230 (for example, width, height, or both) may be equal to the quantity of coded bits. In such examples, the wireless device 205-b, or both the wireless device 205-a and the wireless device 205-b may create a quantity of copies of the base graph 225 equal to the quantity of coded bits and may connect the quantity of copies of the base graph 225 via edge permutation, as described with reference to FIG. 3. In some examples, by performing the lifting operation, the wireless device 205-b, or both the wireless device 205-a and the wireless device 205-b may preserve a degree of each coded bit (for example, a degree distribution of the LDPC code).

The wireless device 205-a and the wireless device 205-b may perform a high-order modulation operation (for example, 256QAM) to map the coded bits to a modulation constellation. In some examples, mapping the coded bits may be associated with an interleaver. The wireless device 205-a and the wireless device 205-b may further implement shaping (for example, probabilistic shaping) to convert a uniform modulation constellation into a non-uniform modulation constellation.

In some examples, the wireless devices 205 may utilize higher order modulation (for example, 16 QAM, 64 QAM, 256 QAM, 1024QAM, 4096QAM) to increase spectral efficiency for wireless transmissions at higher signal-to-noise-ratio (SNR) values. In such examples, constellations of modulated symbols may be fixed (for example, may be square constellations), where each constellation point (for example, value, symbol) may have a same probability of being used as another constellation point (for example, each constellation point may be used with equal probability). In some examples, as SNR increases, the information rate of uniform modulation (for example, 16 QAM, 64 QAM, 256 QAM, QPSK) as well as probabilistic shaping may increase. Optimized constellation distribution may plateau. For example, initially, for a given modulation scheme or shaping scheme, an increase in SNR may result in an increase in information rate, however at some point, SNR may continue to increase while information rate remains the same. Probabilistic shaping may plateau at the same information rate as the 256 QAM, and plateau at higher information rates than other uniform QAM.

In some cases, the distribution of symbols may be shaped such that different symbols may have different probabilities of usage, where such a distribution may be referred to as a non-uniform distribution of symbols. For example, a non-uniform distribution of symbols may include a first set of symbols with respective probabilities of usage below a first probability level and a second set of symbols with respective probabilities of usage above or equal to the first probability level. In such cases, the first set of symbols may include one or more probabilities below the first probability level (for example, different probabilities below the first probability level) and the second set of symbols may include one or more probabilities above or equal to the first probability level (for example, different probabilities above or equal to the first probability level).

A non-uniform distribution (for example, Gaussian-like distribution, a Maxwell-Boltzmann distribution) of symbols may be shaped using one or more probabilistic shaping techniques. Probabilistic shaping may be a technique used to increase spectral efficiency of the coded modulation, and may generate non-uniformly distributed coded modulation symbols, or non-uniformly distributed constellations. In some examples, non-uniformly distributed QAM may have a higher capacity than a uniformly distributed QAM. Such non-uniform distributions may result in higher transmission capacities, higher spectral efficiencies, or generally higher communication quality than uniform symbol distributions. For example, non-uniformly distributed constellations may be associated with a larger mutual information (for example, an information I, defined by parameters X and Y) than uniformly distributed constellations, at the same SNR. Non-uniformly distributed constellations (for example, a Maxwell-Boltzmann distribution) may maximize a source entropy for a given average power. In such cases, inner constellations of the non-uniformly distributed constellations may be used with higher probability levels.

An example of a probabilistic shaping framework may be probabilistic amplitude shaping (PAS) (for example, distribution matching). PAS may shape an amplitude of a constellation of modulated symbols (for example, the amplitude may be non-uniform), while leaving the sign of the constellation uniformly distributed. In some examples, PAS may be performed prior to channel coding of information bits. In some examples, PAS may perform shaping on information bits (for example, shaping the bits for distribution into a non-uniform constellation of symbols), and may utilize systematic channel codes. For example, PAS may use a systematic channel code to preserve the shaping applied to the information bits (for example, the shaping may be preserved during channel coding, which may occur after shaping). In PAS, parity bits may not be shaped, and instead may be mapped to the signs of the constellations (for example, which signs may not be shaped in PAS).

In some examples, the base graph 225 may be designed such that the base graph 225 may be sparser than some other base graph designs for lower complexity implementation (for example, sparser than a base graph design referred to as base graph 1 (BG1) in a 5G NR system) in terms of average variable node degree. For example, the base graph 225 may be designed to support second degree variable nodes in the information nodes (for example, core nodes), and the average degree of the one or more variable nodes of the base graph 225 may decrease (for example, become sparser) relative to other base graph designs. A base graph 225 that is sparse may be less computationally complex and may incur reduced power consumption at a wireless device 205. For example, a base graph 225 that is 13% sparser than another base graph may perform 13% fewer cycles per encoding or decoding iteration. Additionally, the base graph 225 may be designed to support more second degree nodes associated with MSBs than associated with less significant bits, such as the LSB.

In some examples, the base graph 225 may be designed for probabilistic shaping, such as being associated with a PAS procedure. For instance, a first base design (for example, as illustrated by the example base graph 225 of FIG. 2) may apply to uniform shaping procedures, and another base graph design may apply to probabilistic shaping procedures. In such examples, wireless devices 205 may perform lifting on the base graph according to a dual diagonal lifting matrix 230. Similar base graph designs as depicted by the base graph 225 may be implemented specifically for probabilistic shaping scenarios. However, for probabilistic shaping, parity bits and unshaped information bits may be mapped to the MSB of a constellation. In such examples, the base graph 225 may be altered or adjusted to accommodate the mapping of parity bits and unshaped information bits to the MSB. In some examples, the base graph 225 may be the same for uniform QAM and probabilistic shaping. In some examples, the base graph 225 may be different and designed for probabilistic shaping.

The base graph 225 (and/or a base graph designed for probabilistic shaping) may support an improved complexity to performance tradeoff compared to other base graphs. In some examples, based on implementing an LDPC code generated using a base graph 225 that is sparse, one or more communication parameters associated with communications between wireless devices may improve. For example, a threshold SNR may decrease relative to a quantity of modulation iterations normalized with respect to a total quantity of edges of the base graph 225.

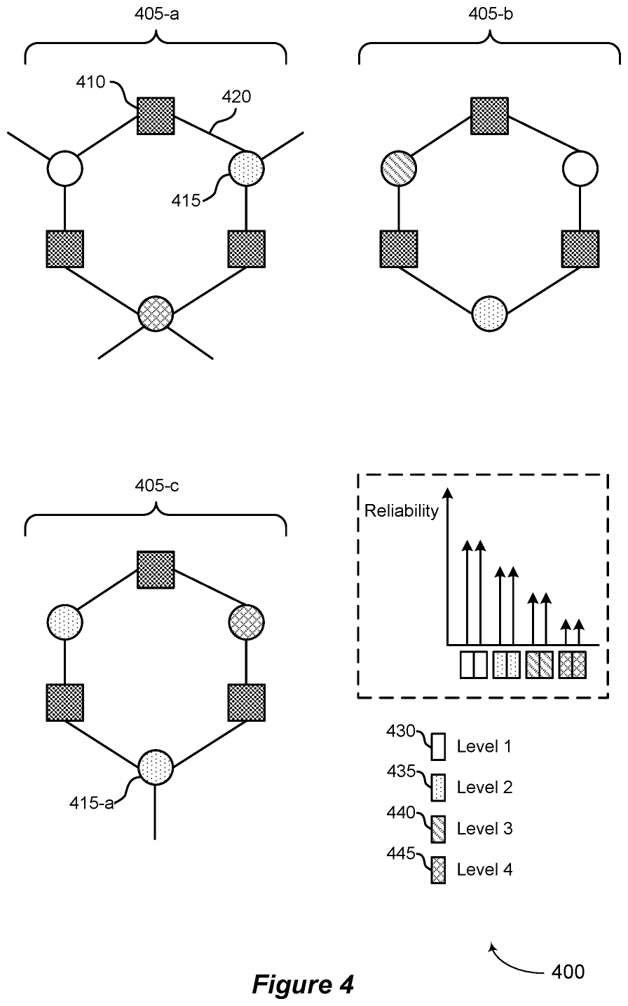

In accordance with examples described herein, lifting schemes (for example, lifting matrices 230) that define an LDPC code may be designed to improve reliability and error floor performance, for example, by considering the reliability of bits in the design of (for example, the cyclic shifts of) the lifting schemes. For example, a lifting scheme may be associated with one or more restrictions, such as being defined such that cycle(s) having a minimum length of the LDPC code may be restricted such that there are no second degree variable nodes, there is at least one third (or higher) degree variable in the cycle, or that LSBs are excluded from the cycles, or a combination thereof. Additional details related to the restrictions associated with the lifting scheme are described herein, including with reference to FIG. 4. Such restrictions may support a smaller girth of the LDPC code (for example, an LDPC code with girth six). LDPC codes with relatively smaller girths may have a relatively smaller variable node degree on average, which may reduce encoding and/or decoding complexity of the LDPC code as throughput scales while increasing a reliability associated with the LDPC code.

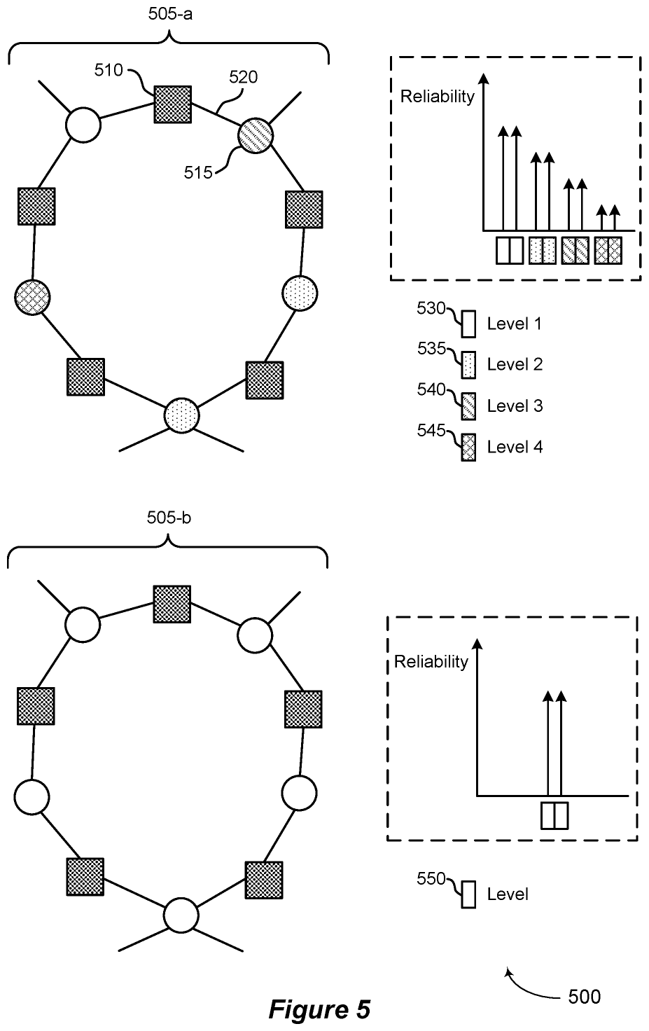

In some examples, the lifting scheme may be defined to maximize a weighted girth of the LDPC code (for example, designed such that a weighted girth of the LDPC code at least satisfies a threshold). For example, each variable node and check node may be assigned (for example, associated with) a weight, and the weighted length of a cycle may be the sum of the weights of nodes included in the cycle. The weighted girth of the LDPC code may be the minimum of the weighted lengths of all cycles of the LDPC code (for example, all cycles of the lifted graph). Weights assigned to variable nodes may be in accordance with a degree of the variable node and/or a reliability of the corresponding bit channel. For example, higher reliabilities and higher degrees may correspond to higher weights. As such, variable nodes corresponding to lower significant bits and/or lower-degree variable nodes may be assigned relatively smaller weights, and thus greater importance in designing the lifting scheme for the LDPC code to maximize the weighted girth, which may improve reliability and error floor performance of bits encoded using such an LDPC code. Additional details related to the maximization of weighted girth are described herein, including with reference to FIG. 5.

In some examples, different lifting schemes may be used in accordance with different modulation orders according to which the wireless devices 205 communicate (for example, use to encode or decode the bits of a signal 220). That is, the wireless devices 205 may use different LDPC codes defined by (for example, generated using) different lifting schemes in accordance with different modulation orders used to communicate signals 220. In some examples, the base graph that defines the different LDPC codes may be the same across the different modulation orders. In some examples, a first lifting scheme may be used for modulation schemes having a modulation order that satisfies (for example, is greater than, is greater than or equal to) a threshold modulation order, and a second lifting may be used for modulation schemes having a modulation order that fails to satisfy (for example, is less than, is less than or equal to) the threshold modulation order.

In some examples, a lifting scheme may be designed for uniform QAM and/or probabilistic shaping. For example, if the base graph 225 is designed for uniform QAM, a first lifting scheme designed for uniform QAM may be used to generate an LDPC code. If the base graph 225 is designed for probabilistic shaping, a second lifting scheme designed for probabilistic shaping may be used to generate an LDPC code. In some examples, if the base graph 225 is the same for uniform QAM and probabilistic shaping, a same lifting scheme may be used. In some other examples, a same base graph 225 may be used for uniform QAM and probabilistic shaping, but different lifting schemes designed for uniform QAM and probabilistic shaping, respectively, may be used to generate corresponding LDPC codes. That is, in some examples, the different LDPC codes for uniform QAM and probabilistic shaping may be associated with the same base graph, but different lifting schemes.

In some examples, use of an LDPC code defined by the base graph 225 and a lifting scheme described herein may be activated or deactivated via signaling. For example, the wireless device 205-a may transmit signaling to the wireless device 205-b (or vice versa), such as downlink control information (DCI), RRC signaling, a MAC-control element (MAC-CE), to activate or deactivate the use of the LDPC code. Additionally, or alternatively, another wireless device 205 may transmit the signaling to the wireless devices 205-a and 205-b (for example, a network entity 105 transmitting the signaling to two UEs 115).

In some examples, use of an LDPC code defined by the base graph 225 and a lifting scheme described herein may be conditioned on both the transmitting and receiving devices supporting the use of the LDPC code. In some examples, a wireless device 205, such as a UE 115, may transmit capability signaling (for example, capability reporting) to another wireless device 205, such as a network entity 105, to indicate its support (or lack of support) for the LDPC code.

FIG. 3 shows a lifting diagram 300 of an example lifting scheme for LDPC codes. The lifting diagram 300 may implement or be implemented by aspects of the wireless communications systems 100 or 200 as described with reference to FIGS. 1 and 2. For example, the lifting diagram 300 may be implemented by a wireless device 205 to generate an LDPC code. In some examples, an LDPC code may be generated in accordance with the lifting diagram 300, and a wireless device 205 may store or otherwise have access to the LDPC code (for example, without generating the LDPC code at the wireless device 205).

In some examples, a base graph, such as a base graph 225, may be represented as a Tanner graph. For example, a base graph 305 may be an example of a Tanner graph representation of a base graph, as compared to the matrix representation of the base graph 225 depicted with reference to FIG. 2. It is noted that the base graph 305 is not the Tanner graph representation of the base graph 225 depicted in FIG. 2, and instead represents another base graph for illustrative clarity. The base graph 305 may include check nodes 310 and variable nodes 315, and the Tanner graph depicts edges 320 between respective check nodes 310 and variable nodes 315, where the edges 320 may correspond to non-zero elements of a matrix representation of the base graph.

In the example of FIG. 3, a base graph 305-a may include check nodes 310-a, 310-b, and 310-c and variable nodes 315-a, 315-b, 315-c, and 315-d. Prior to a lifting operation 325, the variable node 315-a may be connected with check nodes 310-a and 310-b; the variable node 315-b may be connected with check nodes 310-a and 310-c; the variable node 315-c may be connected with check nodes 310-a, 310-b, and 310-c; and the variable node 315-d may be connected with check nodes 310-b and 310-c. As such, the variable nodes 315-a. 315-b, and 315-d may be second degree nodes while the variable node 315-c may be a third degree node.

The base graph 305-a may be lifted in accordance with a lifting scheme that defines a quantity of copies of the base graph 305-a used to generate an LDPC code and respective cyclic shifts associated with connected variable nodes 315 and check nodes 310 of the base graph 305-a and the copies 306 of the base graph 305-a. For instance, in the example of FIG. 3, the lifting scheme may define the use of copies 306-a and 306-b of the base graph 305-a and define how the base graph 305-a and the copies 306-a and 306-b are interconnected to generate the LDPC code. For example, the lifting scheme may define how edges 320 of the base graph 305-a and the copies 306 are permuted to interconnect the base graph 305-a and the copies 306. Cycle shifts defined by the lifting scheme may define the permutations of the edges 320. For example, the cyclic shifts may define cycle permutations of the edges 320 (for example, rather than arbitrary permutations of the edges 320).

In the example of FIG. 3, a first permutation of edges 320 of first variable nodes 315 is depicted. For example, the copy 306-a may include check nodes 310-d, 310-c, and 310-f and variable nodes 315-c, 315-f, 315-g, and 315-h. The copy 306-b may include check nodes 310-g, 310-h, and 310-i and variable nodes 315-i, 315-j. 315-k, and 315-1. Edges 320 among the variable nodes 315 and check nodes 310 corresponding the same variable nodes 315 and check nodes 310 in the base graph 305 may be permuted. For example, an edge 320 from the variable node 315-a to the check node 310-a may be permuted to be an edge 320 from the variable node 315-a to the check node 310-d. Similarly, an edge 320 from the variable node 315-e to the check node 310-d may be permuted to be an edge 320 to the check node 310-g, and an edge 320 from the variable node 315-i to the check node 310-g may be permuted to be an edge to the check node 310-a. It is noted that the lifting diagram 300 depicts a single permutation of edges 320 for illustrative clarity and that additional permutations of the edges 320 may be performed in accordance with the lifting scheme to generate a lifted graph, which may correspond to the LDPC code.

In some cases, performance of a lifting scheme may be increased if the girth of the resulting LDPC code (for example, the length of the smallest cycle in the lifted graph) is increased. In some examples, the degree of each variable node in a cycle is also considered in the design of a lifting scheme. For example, increasing the length of cycles including variable nodes that are all second degree variable nodes may increase performance of the lifting scheme, for example, by decreasing the likelihood of errors in these cycles, which may be referred to as trapping set and be associated with a higher probability of error.

The reliabilities of bits corresponding to variable nodes may be considered in designing a lifting scheme such that reliability and error floor performance may be improved in association with the use of higher order modulation schemes. For example, a lifting scheme may be defined in accordance with one or more restrictions, as described herein including with reference to FIG. 4. Additionally, or alternatively, a lifting scheme may be defined to increase (for example, maximize) a minimum weighted girth of a resulting LDPC code, as described herein including with reference to FIG. 5.

FIG. 4 shows a cycle diagram 400 of an example lifting scheme for LDPC codes. The cycle diagram 400 may implement or be implemented by aspects of the wireless communications systems 100 or 200 as described with reference to FIGS. 1 and 2. For example, the cycle diagram 400 depicts various cycles 405 that may be included in a lifted graph generated in accordance with a lifting scheme described herein associated with generating an LDPC code.

The lifting scheme may be designed in accordance with one or more restrictions to improve reliability and error floor performance associated with a resulting LDPC code used to encode and/or decode bits signaled between wireless devices. For example, a base graph and a lifting scheme may be designed such that a girth of the corresponding LDPC code is reduced relative to other base graph and lifting schemes. For example, in some cases, other base graphs and lifting schemes may be designed such that the girth is eight. In some examples, the base graph and lifting scheme may be designed such that the corresponding LDPC code may include smaller-length cycles, such as length-six cycles. Such designs may enable the use of sparser base graphs to support lower complexity implementations and throughput scaling, as described with reference to FIG. 2.

In some cases, smaller length cycles may be associated with relatively lower reliability. For example, a bit corresponding to a variable node included in a relatively smaller length cycle may have a lower reliability than a bit corresponding to a variable node included in a relatively longer length cycle. Additionally, or alternatively, in some examples, one or more coded bits associated with an LDPC code may be transmitted or received through different channels, for example, if using higher-order modulation schemes. Each channel may be associated with a reliability. In some cases (for example, higher-order QAM), one or more bits may occupy a same modulation symbol in time. In such cases, a first bit associated with a first modulation level may have a different significance than a second bit associated with a second modulation. For example, bits coded in accordance with a modulation scheme may be associated with one of multiple modulation levels, such as a level 1 430 (for example, a MSB), a level 2 435 (for example, a second MSB), a level 3 440 (for example, a third MSB), and a level 4 445 (for example, a LSB). In such examples, a lower numerical value associated with the modulation level may correspond to a higher bit significance and a higher reliability (for example, a MSB may be associated with modulation level 1 with a highest reliability, while a LSB may be associated with modulation level 4 with a lowest reliability). For example, MSBs may be associated with a most reliable bit location of the modulation scheme, second MSBs may be associated with a second most reliable bit location of the modulation scheme, and so on such that LSBs may be associated with a least reliable bit location of a modulation scheme.

Cyclic shifts of a lifting scheme may be defined in accordance with one or more restrictions such that a reliability of bits included in a minimum length cycle (for example, a length-six cycle) may be increased. For example, the cycle diagram 400 depicts cycles 405-a, 405-b, and 405-c. The cycles 405 may be examples of a minimum length cycle included in a LDPC code defined by a base graph and a lifting scheme described herein. A minimum length cycle may be a cycle 405 associated with (for example, having) the girth of the LDPC code. In the example of FIG. 4, the cycles 405 may be length-six cycles that include three check nodes 410 and three variable nodes 415 that are connected by respective edges 420.

In some examples, the one or more restrictions may restrict second degree variable nodes 415 from being included in a minimum length cycle. For example, the cycle 405-a may include three variable nodes 415 each of which are at least third degree variable nodes 415. That is, each variable node 415 in the cycle 405-a may be a third degree variable node 415 or a higher degree node 415 such that second degree variable nodes are excluded from the cycle 405-a.

In some examples, the one or more restrictions may restrict variable nodes associated with LSBs from being included in a minimum length cycle. For example, the cycle 405-b may include three variable nodes 415, none of which correspond to an LSB (for example, bits associated with a level 4 445). For instance, in accordance with the one or more restrictions, the cycle 405-b may exclude variable nodes 415 that correspond to LSBs.

In some examples, the one or more restrictions may indicate that at least one variable node 415 included in a minimum length cycle is a third or higher degree variable node 415. For example, the one or more restrictions may indicate that one or more second degree variable nodes 415 may be included in the minimum length cycle if at least one variable node 415 of the third degree or higher is also included in the minimum length cycle. For instance, the cycle 405-c may include three variable nodes 415, and at least one of the three variable nodes 415 (for example, a variable node 415-a) is a third or higher degree variable node 415. In the example of the cycle 405-c, the variable node 415-a may be a third degree variable node.

In some examples, the one or more restrictions may indicate that second degree variable nodes 415 may be included in a minimum length cycle, but no second degree variable nodes 415 that are associated with LSBs may be included in the minimum length cycle. For example, the cycle 405-b may include second degree variable nodes 415, none of which correspond to an LSB. For instance, in the example of FIG. 4, each second degree variable node included in the cycle 405-b is associated with a level 3 or higher modulation level.

Various combinations of the restrictions are possible. For example, the cycle 405-a may include variable nodes 415 that are associated with LSBs, but may be in accordance with a restriction that second degree variable nodes 415 are excluded from minimum length cycles. The cycle 405-b may include exclude variable nodes 415 of the third degree or higher, but may be in accordance with a restriction that variable nodes 415 associated with LSBs are excluded from minimum length cycles. Other combinations of the restrictions are possible.

Defining cycle shifts of a lifting scheme in accordance with one or more restrictions described herein may increase reliability and improve error floor performance of an LDPC code defined by the lifting scheme. For example, trapping set cycles having the minimum length may be avoided by restricting minimum length cycles such that they include one or more variable nodes of the third degree or higher, thereby increasing reliability of the bits corresponding to nodes included in the minimum length cycles. Additionally, or alternatively, bits included in minimum length cycles may be restricted such that lower (for example, least) reliable bits are excluded from the minimum length cycles.

FIG. 5 shows a cycle diagram 500 of an example lifting scheme for LDPC codes. The cycle diagram 400 may implement or be implemented by aspects of the wireless communications systems 100 or 200 as described with reference to FIGS. 1 and 2. For example, the cycle diagram 400 depicts various cycles 405 that may be included in a lifted graph generated in accordance with a lifting scheme described herein associated with generating an LDPC code.

The lifting scheme may be designed to increase (for example, maximize) a weighted girth of a resulting LDPC code to improve reliability and error floor performance associated with the LDPC code. For example, as described with reference to FIG. 4, coded bits associated with an LDPC code may be associated with varying levels of reliability, such as due to implementing a higher order modulation scheme having multiple modulation levels. Each coded bit may correspond to a respective modulation level of the higher order modulation scheme. For instance, bits coded in accordance with a modulation scheme may be associated with one of multiple modulation levels, such as a level 1 530 (for example, a MSB), a level 2 535 (for example, a second MSB), a level 3 540 (for example, a third MSB), and a level 4 545 (for example, a LSB). In such examples, a lower numerical value associated with the modulation level may correspond to a higher bit significance and a higher reliability (for example, a MSB may be associated with modulation level 1 with a highest reliability, while a LSB may be associated with modulation level 4 with a lowest reliability).

In some other examples, coded bits associated with an LDPC code may be associated with a same level of reliability. For example, for a lower order modulation scheme in which each bit is transmitted or received through a same channel (for example, a QPSK modulation scheme), each bit may be associated with a same modulation level, such as a level 550.

The cycle diagram 500 depicts cycles 505-a and 505-b. Each cycle 505 may include various quantities of check nodes 510 and variable nodes 515 that are connected by respective edges 520. The cycles 505 may be examples of a cycle included in a LDPC code that is associated with (for example, has) the weighted girth (for example, minimum weighted cycle length) of the LDPC code. Cyclic shifts of a lifting scheme may be defined to increase (for example, maximize) a weighted girth of a corresponding LDPC code. For example, the cycle shifts may be defined such that a weighted length of a cycle 505 satisfies (for example, is greater than, is greater than or equal to) a threshold weighted girth (for example, a threshold weighted cycle length).

Weights may be assigned to nodes in a cycle 505, and the weights may be used to determine (for example, calculate) a weighted length of the cycle 505 (for example, rather than length of the cycle 505 corresponding to the quantity of nodes included in the cycle 505). For example, the weighted length of a cycle 505 may be a sum of the weights of the nodes included in the cycle 505. Respective variable nodes 515 may be associated with weights that are defined in accordance with a reliability (for example, a modulation level) of one or more bits corresponding to the variable node 515 and/or a degree of the variable node 515. In some examples, respective check nodes 515 may similarly be associated with weights that are defined in accordance with a reliability of one or more bits corresponding to the check node 510 and/or a degree of the check node 510. In some other examples, each check node 510 may be associated with (for example, assigned) a same weight.

In some examples, higher degree variable nodes 515 may be assigned higher weights than lower degree variable nodes 515. For example, a third degree variable node 515 may be assigned a higher weight than a second degree variable node 515, a fourth degree variable node 515 may be assigned a higher weight than a third degree variable node, and so on. In some examples, higher degree check nodes 510 may similarly be associated with higher weights than lower degree check nodes 510.

In some examples, variable nodes 515 associated with more significant bits (for example, higher reliabilities) may be assigned higher weights than variable nodes associated with less significant bits. For example, a variable node 515 corresponding to one or more LSBs may be assigned a lower weight than a variable node 515 corresponding to one or more third MSBs, and so on. In some examples, check nodes 510 associated with more significant bits may similarly be assigned higher weights than check nodes 510 associated with less significant bits.

In some examples, weight assignments may consider both a degree of the variable node 515 and a reliability associated with the variable node 515. For example, the cycle 505-a may be associated with a modulation scheme in which coded bits may be associated with varying levels of reliability, such as level 1 530 through level 4 545. Here, the weights assigned to the variable nodes 515 of the cycle 505-a may be defined in accordance with a respective degree of each variable node 515 and a reliability (for example, modulation level) of one or more bits to which the variable node 515 corresponds. For example, a modulation order of the modulation scheme associated with the cycle 505-a may satisfy (for example, be greater than, be greater than or equal to) a threshold order such that the respective weights are defined in accordance with the respective degree and reliability. In some examples, the threshold order may correspond to a modulation order which, if satisfied, corresponds to coded bits being transmitted or received through different channels. In some examples, weight assignments may similarly consider both a degree of a check node 510 and a reliability associated with the check node 510.

In some examples, a degree of the variable node 515 may factor into the weight assignment of the variable node 515 more than a reliability associated with the variable node 515. For example, a first weight of a first variable node 515 having a degree that is higher than a degree of a second variable node 515 may be higher than a second weight of the second variable node 515 even if a reliability associated with the second variable node 515 is higher than a reliability associated with the first variable node 515 (for example, the second variable node 515 corresponds to more significant bits than bits to which the first variable node 515 corresponds). In some examples, a degree of the check node 510 may similarly factor into the weight assignment of the check node 510 more than a reliability associated with the check node 510.

In some other examples, a reliability associated with the variable node 515 may factor into the weight assignment of the variable node 515 more than a degree of the variable node 515. For example, a first weight of a first variable node 515 associated with a first reliability that is higher than a second reliability associated a second variable node 515 may be higher than a second weight of the second variable node 515 even if a degree of the second variable node 515 is higher than a degree of the first variable node 515 (for example, the first variable node 515 corresponds to more significant bits than bits to which the second variable node 515 corresponds). In some examples, a reliability associated with the check node 510 may similarly factor into the weight assignment of the check node 510 more than a degree of the check node 510.

The cycle 505-b may be associated with a modulation scheme in which coded bits may be associated with a same level of reliability, such as level 550. Here, the weights assigned to the variable nodes 515 of the cycle 505-b may be defined in accordance with a respective degree of each variable node 515. For example, a modulation order of the modulation scheme associated with the cycle 505-a may fail to satisfy (for example, be less than, be less than or equal to) a threshold order such that the respective weights are defined in accordance with the respective degree and reliability. In some examples, the threshold order may correspond to a modulation order which, if unsatisfied, corresponds to coded bits being transmitted or received through a same channel. As such, a reliability associated with each variable node 515 may be the same, and the weight assignment may be based solely on the respective degree of each variable node 515. Similarly, in some examples, a reliability associated with each check node 510 may be the same, and the weight assignment may be based solely on the respective degree of each check node 510.

Various weight assignment schemes are possible. For example, weights may be ordered with respect to degrees, as depicted in Table 1 below. In some other examples, weights may be incremented with respect to higher channel reliability, as depicted in Tables 2-4 below.

TABLE 1

| Reliability | Degree (2, 3, 4) |
|---|---|
| LBS1 | (1, 9, 16) |
| LBS2 | (3, 11, 16) |
| LBS3 | (5, 13, 16) |
| LSB4 (MSB) | (7, 15, 16) |
| Punctured | 16 |

TABLE 2

| Reliability | Degree (2, 3, 4) |
|---|---|
| LBS1 | (1, 3, 4) |
| LBS2 | (1, 3, 4) + 1 |
| LBS3 | (1, 3, 4) + 2 |
| LSB4 (MSB) | (1, 3, 4) + 3 |
| Punctured | 5 |

TABLE 3

| Reliability | Degree (2, 3, 4) |
|---|---|
| LBS1 | (1, 3, 4) |
| LBS2 | (1, 3, 4) + 2 |
| LBS3 | (1, 3, 4) + 4 |
| LSB4 (MSB) | (1, 3, 4) + 6 |
| Punctured | 5 |

TABLE 4

| Reliability | Degree (2, 3, 4) |
|---|---|
| LBS1 | (1, 3, 4) |
| LBS2 | (1, 3, 4) + 3 |
| LBS3 | (1, 3, 4) + 6 |
| LSB4 (MSB) | (1, 3, 4) + 9 |
| Punctured | 5 |

As depicted in Table 1, variable nodes 515 (for example, and/or check node 510) of higher degrees may be assigned a higher weight than variable nodes of lower degrees, regardless of the reliability associated with the variable nodes. Additionally, weights assigned to variable nodes 515 of a same degree may increase with increasing associated reliability.

Tables 2-4 depict various examples of increments that may be added to weights in accordance with increasing reliability. For example, weights may increase with increasing degree of a variable node 515 (for example, and/or a check node 510), and each degree may correspond to a respective weight. Based on the reliability of the variable node, an increasing increment may be added to the weight corresponding to the degree of the variable node.

In some examples, a weight assigned to a variable node 515 and/or a check node 510 may be in accordance with whether the node is a punctured node. For example, the weights of punctured nodes may be fixed (for example, regardless of the degree of the punctured node). In the example weight assignment scheme of Table 1, the weight assigned to punctured nodes may be 16, whereas in the example weight assignment scheme of Tables 2-4, the weight assigned to punctured nodes may be 5, however, any value of fixed weights may be used.

In some examples, a threshold weighted girth to be satisfied may depend on the weight assignment scheme implemented. For example, a threshold weighted girth associated with Table 1 may be higher than a threshold weighted girth associated with Tables 2-4. Additionally, a threshold weighted girth of Table 4 may be higher than a threshold weighted girth of Table 3 in accordance with using higher increment values, and so on.

By defining cycle shifts to increase a weighted girth (for example, a minimum weighted cycle length) of a corresponding LDPC code, lower-degree variable nodes 515 and/or variable nodes 515 associated with lower reliabilities may be assigned smaller weights. Additionally, or alternatively, lower-degree check nodes 510 and/or check nodes 510 associated with lower reliabilities may be assigned smaller weights. As such, these variable nodes 515 and/or check node 510 may have greater importance in designing the lifting scheme in order to increase the weighted girth of a corresponding LDPC code, which may improve reliability and error floor performance of bits encoded using such an LDPC code.

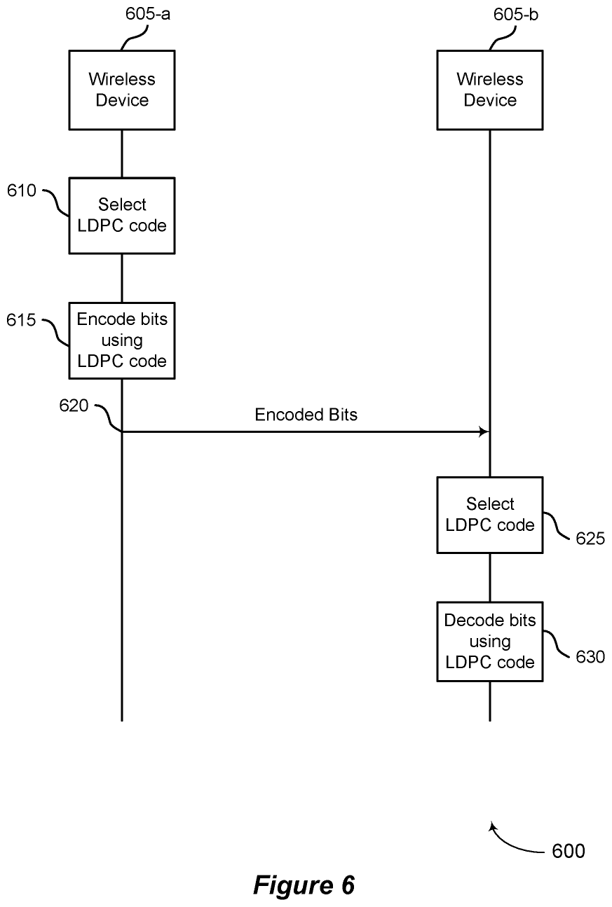

FIG. 6 shows an example process flow 600 that supports lifting schemes for LDPC codes. The process flow 600 may implement or be implemented by aspects of the wireless communications system 100 and the wireless communications system 200 as described herein with reference to FIGS. 1 and 2. For instance, the process flow 600 may be implemented by wireless devices 605-a and 605-b, which may be examples of a network entity 105 or a UE 115. A device transmitting a signal, or a message, (for example, in the uplink, downlink, or sidelink) may be referred to as a transmitting device, and a device receiving the transmitted signal (for example, in the uplink, downlink, or sidelink) may be referred to as a receiving device.

In the following description of the process flow 600, the operations between the wireless devices 605 may be transmitted in a different order than the example order shown, or the operations between the wireless devices 605 may be performed in different orders at different times. Some operations may also be omitted from the process flow 600, and other operations may be added to the process flow 600.

At 610, the wireless device 605-a may select an LDPC code according to which to encode a set of bits. For example, the wireless device 605-a may store or otherwise have access to a set of LDPC codes. In some examples, the wireless device 605-a may select the LDPC code in accordance with a modulation order of a modulation scheme associated with encoding the set of bits. For example, if the modulation order satisfies a threshold modulation order, the wireless device 605-a may select a first LDPC code defined by a first lifting scheme. If the modulation order fails to satisfy a threshold modulation order, the wireless device 605-a may select a second LDPC code defined by a second lifting scheme.

At 615, the wireless device 605-a may encode the set of bits using the selected LDPC code. The LDPC code may be defined by a lifting scheme defined in accordance with one or more restrictions and/or such that a weighted girth of the LDPC code satisfies a threshold weighted girth.

At 620, the wireless device 605-a may transmit a signal to the wireless device 605-b that includes the set of encoded bits.

At 625, the wireless device 605-b may receive the signal and select the LDPC code to decode the set of encoded bits. For example, the wireless device 605-b may store or otherwise have access to the set of LDPC codes. The wireless device 605-b may select the LDPC code from the set of LDPC codes in accordance with a modulation order of a modulation scheme associated with decoding the set of bits, which may be the same modulation scheme used by the wireless device 605-a to encode the set of bits.

At 630, the wireless device 605-b may decode the bits using the LDPC code.

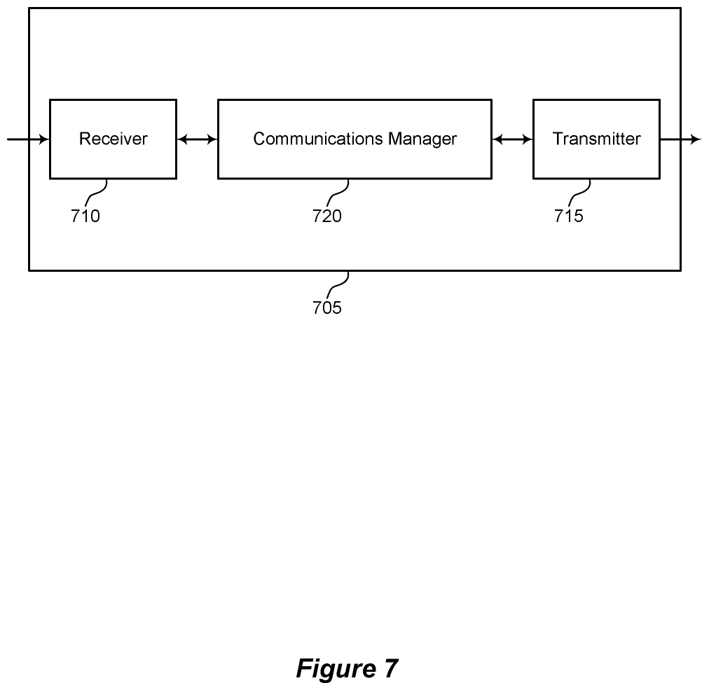

FIG. 7 shows a block diagram of an example wireless communications device 705 that supports lifting schemes for LDPC codes. The device 705 may be an example of aspects of a UE 115 or a network entity 105 as described herein. The device 705 may include a receiver 710, a transmitter 715, and a communications manager 720. The device 705, or one or more components of the device 705 (for example, the receiver 710, the transmitter 715, and the communications manager 720), may include at least one processor, which may be coupled with at least one memory, to, individually or collectively, support or enable the described techniques. Each of these components may be in communication with one another (for example, via one or more buses).

The receiver 710 may provide a means for receiving information such as packets, user data, control information, or any combination thereof associated with various information channels (for example, control channels, data channels, information channels related to lifting schemes for LDPC codes). Information may be passed on to other components of the device 705. The receiver 710 may utilize a single antenna or a set of multiple antennas.

The transmitter 715 may provide a means for transmitting signals generated by other components of the device 705. For example, the transmitter 715 may transmit information such as packets, user data, control information, or any combination thereof associated with various information channels (for example, control channels, data channels, information channels related to lifting schemes for LDPC codes). In some examples, the transmitter 715 may be co-located with a receiver 710 in a transceiver module. The transmitter 715 may utilize a single antenna or a set of multiple antennas.

The communications manager 720, the receiver 710, the transmitter 715, or various combinations thereof or various components thereof may be examples of means for performing various aspects of lifting schemes for LDPC codes as described herein. For example, the communications manager 720, the receiver 710, the transmitter 715, or various combinations or components thereof may be capable of performing one or more of the functions described herein.

In some examples, the communications manager 720, the receiver 710, the transmitter 715, or various combinations or components thereof may be implemented in hardware (for example, in communications management circuitry). The hardware may include at least one of a processor, a digital signal processor (DSP), a central processing unit (CPU), an application-specific integrated circuit (ASIC), a field-programmable gate array (FPGA) or other programmable logic device, a microcontroller, discrete gate or transistor logic, discrete hardware components, or any combination thereof configured as or otherwise supporting, individually or collectively, a means for performing the functions described in the present disclosure. In some examples, at least one processor and at least one memory coupled with the at least one processor may be configured to perform one or more of the functions described herein (for example, by one or more processors, individually or collectively, executing instructions stored in the at least one memory).

Additionally, or alternatively, the communications manager 720, the receiver 710, the transmitter 715, or various combinations or components thereof may be implemented in code (for example, as communications management software or firmware) executed by at least one processor. If implemented in code executed by at least one processor, the functions of the communications manager 720, the receiver 710, the transmitter 715, or various combinations or components thereof may be performed by a general-purpose processor, a DSP, a CPU, an ASIC, an FPGA, a microcontroller, or any combination of these or other programmable logic devices (for example, configured as or otherwise supporting, individually or collectively, a means for performing the functions described in the present disclosure).

In some examples, the communications manager 720 may be configured to perform various operations (for example, receiving, obtaining, monitoring, outputting, transmitting) using or otherwise in cooperation with the receiver 710, the transmitter 715, or both. For example, the communications manager 720 may receive information from the receiver 710, send information to the transmitter 715, or be integrated in combination with the receiver 710, the transmitter 715, or both to obtain information, output information, or perform various other operations as described herein.

The communications manager 720 may support wireless communication in accordance with examples as disclosed herein. For example, the communications manager 720 is capable of, configured to, or operable to support a means for encoding a set of bits in accordance with a LDPC code associated with (for example, defined by) a base graph and a lifting scheme, where the base graph includes a set of multiple check nodes and a set of multiple variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the set of bits, or a combination thereof. The communications manager 720 is capable of, configured to, or operable to support a means for transmitting a signal including the encoded set of bits.

Additionally, or alternatively, the communications manager 720 may support wireless communication in accordance with examples as disclosed herein. For example, the communications manager 720 is capable of, configured to, or operable to support a means for receiving a signal including an encoded set of bits. The communications manager 720 is capable of, configured to, or operable to support a means for decoding the encoded set of bits in accordance with a LDPC code associated with (for example, defined by) a base graph and a lifting scheme, where the base graph includes a set of multiple check nodes and a set of multiple variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the encoded set of bits, or a combination thereof.

Additionally, or alternatively, the communications manager 720 may support wireless communication in accordance with examples as disclosed herein. For example, the communications manager 720 is capable of, configured to, or operable to support a means for encoding a set of bits in accordance with a LDPC code associated with (for example, defined by) a base graph and a lifting scheme, where the base graph comprises a set of multiple variable nodes and a set of multiple check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes. The communications manager 720 is capable of, configured to, or operable to support a means for transmitting a signal including the encoded set of bits.

Additionally, or alternatively, the communications manager 720 may support wireless communication in accordance with examples as disclosed herein. For example, the communications manager 720 is capable of, configured to, or operable to support a means for receiving a signal including an encoded set of bits. The communications manager 720 is capable of, configured to, or operable to support a means for decoding the encoded set of bits in accordance with a LDPC code associated with (for example, defined by) a base graph and a lifting scheme, where the base graph includes a set of multiple of variable nodes and a set of multiple of check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes.

By including or configuring the communications manager 720 in accordance with examples as described herein, the device 705 (for example, at least one processor controlling or otherwise coupled with the receiver 710, the transmitter 715, the communications manager 720, or a combination thereof) may support techniques for reduced processing, reduced power consumption, and reduced decoding complexity.

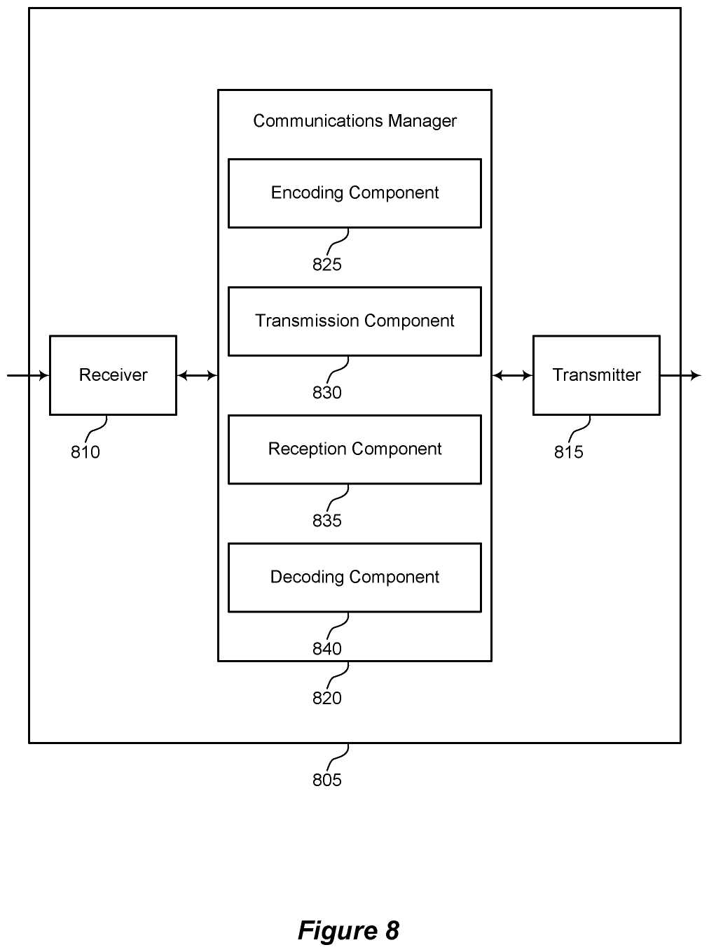

FIG. 8 shows a block diagram of an example wireless communications device 805 that supports lifting schemes for LDPC codes. The device 805 may be an example of aspects of a device 705, a UE 115, or a network entity 105 as described herein. The device 805 may include a receiver 810, a transmitter 815, and a communications manager 820. The device 805, or one of more components of the device 805 (for example, the receiver 810, the transmitter 815, and the communications manager 820), may include at least one processor, which may be coupled with at least one memory, to support the described techniques. Each of these components may be in communication with one another (for example, via one or more buses).

The receiver 810 may provide a means for receiving information such as packets, user data, control information, or any combination thereof associated with various information channels (for example, control channels, data channels, information channels related to lifting schemes for LDPC codes). Information may be passed on to other components of the device 805. The receiver 810 may utilize a single antenna or a set of multiple antennas.

The transmitter 815 may provide a means for transmitting signals generated by other components of the device 805. For example, the transmitter 815 may transmit information such as packets, user data, control information, or any combination thereof associated with various information channels (for example, control channels, data channels, information channels related to lifting schemes for LDPC codes). In some examples, the transmitter 815 may be co-located with a receiver 810 in a transceiver module. The transmitter 815 may utilize a single antenna or a set of multiple antennas.

The device 805, or various components thereof, may be an example of means for performing various aspects of lifting schemes for LDPC codes as described herein. For example, the communications manager 820 may include an encoding component 825, a transmission component 830, a reception component 835, a decoding component 840, or any combination thereof. The communications manager 820 may be an example of aspects of a communications manager 720 as described herein. In some examples, the communications manager 820, or various components thereof, may be configured to perform various operations (for example, receiving, obtaining, monitoring, outputting, transmitting) using or otherwise in cooperation with the receiver 810, the transmitter 815, or both. For example, the communications manager 820 may receive information from the receiver 810, send information to the transmitter 815, or be integrated in combination with the receiver 810, the transmitter 815, or both to obtain information, output information, or perform various other operations as described herein.

The communications manager 820 may support wireless communication in accordance with examples as disclosed herein. The encoding component 825 is capable of, configured to, or operable to support a means for encoding a set of bits in accordance with a LDPC code associated with (for example, defined by) a base graph and a lifting scheme, where the base graph includes a set of multiple check nodes and a set of multiple variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the set of bits, or a combination thereof. The transmission component 830 is capable of, configured to, or operable to support a means for transmitting a signal including the encoded set of bits.

Additionally, or alternatively, the communications manager 820 may support wireless communication in accordance with examples as disclosed herein. The reception component 835 is capable of, configured to, or operable to support a means for receiving a signal including an encoded set of bits. The decoding component 840 is capable of, configured to, or operable to support a means for decoding the encoded set of bits in accordance with a LDPC code associated with (for example, defined by) a base graph and a lifting scheme, where the base graph includes a set of multiple check nodes and a set of multiple variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the encoded set of bits, or a combination thereof.

Additionally, or alternatively, the communications manager 820 may support wireless communication in accordance with examples as disclosed herein. The encoding component 825 is capable of, configured to, or operable to support a means for encoding a set of bits in accordance with a LDPC code associated with (for example, defined by) a base graph and a lifting scheme, where the base graph comprises a set of multiple variable nodes and a set of multiple check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes. The transmission component 830 is capable of, configured to, or operable to support a means for transmitting a signal including the encoded set of bits.

Additionally, or alternatively, the communications manager 820 may support wireless communication in accordance with examples as disclosed herein. The reception component 835 is capable of, configured to, or operable to support a means for receiving a signal including an encoded set of bits. The decoding component 840 is capable of, configured to, or operable to support a means for decoding the encoded set of bits in accordance with a LDPC code associated with (for example, defined by) a base graph and a lifting scheme, where the base graph includes a set of multiple of variable nodes and a set of multiple of check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes.

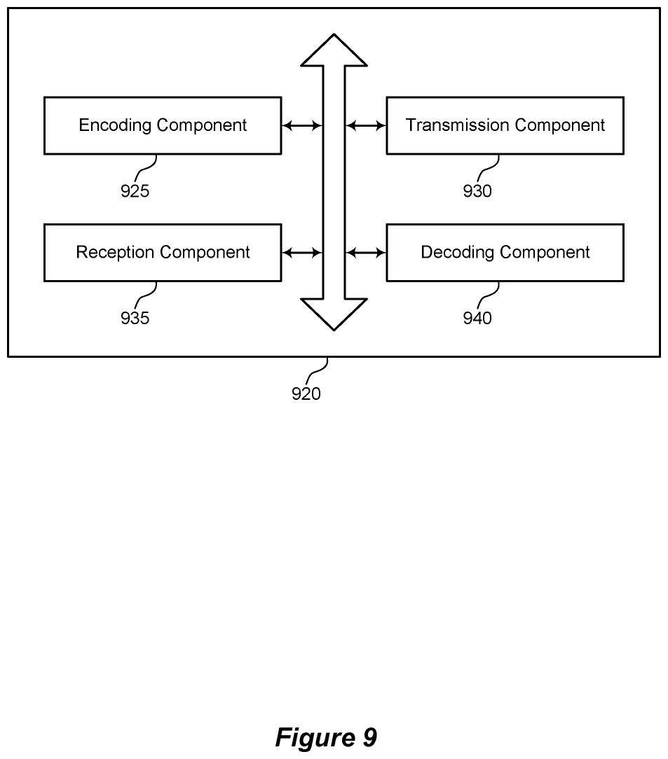

FIG. 9 shows a block diagram of an example communications manager 920 that supports lifting schemes for LDPC codes. The communications manager 920, or various components thereof, may be an example of means for performing various aspects of lifting schemes for LDPC codes as described herein. For example, the communications manager 920 may include an encoding component 925, a transmission component 930, a reception component 935, a decoding component 940, or any combination thereof. Each of these components, or components or subcomponents thereof (for example, one or more processors, one or more memories), may communicate, directly or indirectly, with one another (for example, via one or more buses).

The communications manager 920 may support wireless communication in accordance with examples as disclosed herein. The encoding component 925 is capable of, configured to, or operable to support a means for encoding a set of bits in accordance with a LDPC code associated with (for example, defined by) a base graph and a lifting scheme, where the base graph includes a set of multiple check nodes and a set of multiple variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the set of bits, or a combination thereof. The transmission component 930 is capable of, configured to, or operable to support a means for transmitting a signal including the encoded set of bits.

In some examples, the second degree variable nodes are excluded from the one or more cycles associated with the minimum length in accordance with the restriction.

In some examples, the nodes associated with the least significant bits are excluded from the one or more cycles associated with the minimum length in accordance with the restriction.

In some examples, in accordance with the restriction, at least one third degree variable node is included in a cycle of the one or more cycles associated with the minimum length that includes at least one second degree variable node.

In some examples, in accordance with the restriction, a cycle of the one or more cycles associated with the minimum length excludes second degree variable nodes associated with the least significant bits and includes a second degree variable node associated with one or more bits of the set of bits that are more significant than the least significant bits.

In some examples, the minimum length corresponds to a length-six cycle.

In some examples, the respective cycle shifts are further defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes, respective reliabilities of bits corresponding to the variable nodes, or a combination thereof.

In some examples, a first weight of a first variable node is greater than a second weight of a second variable node in accordance with the first variable node being associated with a greater degree than the second variable node.

In some examples, the second variable node is associated with one or more bits that are more significant than one or more bits associated with the first variable node.

In some examples, a first weight of a first variable node is greater than a second weight of a second variable node in accordance with the first variable node being associated with a higher reliability than the second variable node.

In some examples, a first weight of a first variable node is greater than a second weight of a second variable node in accordance with the first variable node being associated with one or more bits that are more significant than one or more bits associated with the second variable node.

In some examples, the respective weights of the variable nodes are defined by whether the variable nodes correspond to punctured nodes of the base graph.

In some examples, the respective weights of the variable nodes are defined by the respective degrees of the variable nodes and the respective reliabilities in accordance with a modulation order associated with the set of bits satisfying a threshold order.

In some examples, the respective weights of the variable nodes are defined by the respective degrees of the variable nodes in accordance with a modulation order associated with the set of bits failing to satisfy a threshold order.

In some examples, a girth of the LDPC code fails to satisfy the threshold.

In some examples, the least significant bits of the set of bits are associated with a least reliable bit location of a modulation scheme for encoding the set of bits.

In some examples, the lifting scheme is associated with a first modulation scheme having a first modulation order, and the encoding component 925 is capable of, configured to, or operable to support a means for encoding a second set of bits in accordance with a second LDPC code defined by the base graph and a second lifting scheme, where the second lifting scheme is associated with a second modulation scheme having a second modulation order. In some examples, the transmission component 930 is capable of, configured to, or operable to support a means for transmitting a second signal including the encoded second set of bits.

In some examples, the encoding component 925 is capable of, configured to, or operable to support a means for selecting the LDPC code to encode the set of bits in accordance with encoding the set of bits according to the first modulation scheme and the first modulation order satisfying a threshold. In some examples, the encoding component 925 is capable of, configured to, or operable to support a means for selecting the second LDPC code to encode the second set of bits in accordance with encoding the second set of bits according to the second modulation scheme and the second modulation order failing to satisfy the threshold.

In some examples, the lifting scheme is associated with a uniform QAM scheme, and the encoding component 925 is capable of, configured to, or operable to support a means for encoding a second set of bits in accordance with a second LDPC code defined by the base graph and a second lifting scheme, where the second lifting scheme is associated with probabilistic shaping. In some examples, the transmission component 930 is capable of, configured to, or operable to support a means for transmitting a second signal including the encoded second set of bits.

Additionally, or alternatively, the communications manager 920 may support wireless communication in accordance with examples as disclosed herein. The reception component 935 is capable of, configured to, or operable to support a means for receiving a signal including an encoded set of bits. The decoding component 940 is capable of, configured to, or operable to support a means for decoding the encoded set of bits in accordance with a LDPC code associated with (for example, defined by) a base graph and a lifting scheme, where the base graph includes a set of multiple check nodes and a set of multiple variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the encoded set of bits, or a combination thereof.

In some examples, the second degree variable nodes are excluded from the one or more cycles associated with the minimum length in accordance with the restriction.

In some examples, the nodes associated with the least significant bits are excluded from the one or more cycles associated with the minimum length in accordance with the restriction.

In some examples, in accordance with the restriction, at least one third degree variable node is included in a cycle of the one or more cycles associated with the minimum length that includes at least one second degree variable node.

In some examples, in accordance with the restriction, a cycle of the one or more cycles associated with the minimum length excludes second degree variable nodes associated with the least significant bits and includes a second degree variable node associated with one or more bits of the encoded set of bits that are more significant than the least significant bits.

In some examples, the minimum length corresponds to a length-six cycle.

In some examples, the respective cycle shifts are further defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes, respective reliabilities of bits corresponding to the variable nodes, or a combination thereof.

In some examples, a first weight of a first variable node is greater than a second weight of a second variable node in accordance with the first variable node being associated with a greater degree than the second variable node.

In some examples, the second variable node is associated with one or more bits that are more significant than one or more bits associated with the first variable node.

In some examples, a first weight of a first variable node is greater than a second weight of a second variable node in accordance with the first variable node being associated with a higher reliability than the second variable node.

In some examples, a first weight of a first variable node is greater than a second weight of a second variable node in accordance with the first variable node being associated with one or more bits that are more significant than one or more bits associated with the second variable node.

In some examples, the respective weights of the variable nodes are defined by whether the variable nodes correspond to punctured nodes of the base graph.

In some examples, the respective weights of the variable nodes are defined by the respective degrees of the variable nodes and the respective reliabilities in accordance with a modulation order associated with the encoded set of bits satisfying a threshold order.

In some examples, the respective weights of the variable nodes are defined by the respective degrees of the variable nodes in accordance with a modulation order associated with the set of bits failing to satisfy a threshold order.

In some examples, a girth of the LDPC code fails to satisfy the threshold.

In some examples, the least significant bits of the set of bits are associated with a least reliable bit location of a modulation scheme for encoding the set of bits.

In some examples, the lifting scheme is associated with a first modulation scheme having a first modulation order, and the reception component 935 is capable of, configured to, or operable to support a means for receiving a second signal including a second set of encoded bits. In some examples, the decoding component 940 is capable of, configured to, or operable to support a means for decoding the second set of bits in accordance with a second LDPC code defined by the base graph and a second lifting scheme, where the second lifting scheme is associated with a second modulation scheme having a second modulation order.

In some examples, the decoding component 940 is capable of, configured to, or operable to support a means for selecting the LDPC code to decode the set of bits in accordance with decoding the set of bits according to the first modulation scheme and the first modulation order satisfying a threshold. In some examples, the decoding component 940 is capable of, configured to, or operable to support a means for selecting the second LDPC code to decode the second set of bits in accordance with decoding the second set of bits according to the second modulation scheme and the second modulation order failing to satisfy the threshold.

In some examples, the lifting scheme is associated with a uniform QAM scheme, and the reception component 935 is capable of, configured to, or operable to support a means for receiving a second signal including a second set of encoded bits. In some examples, the decoding component 940 is capable of, configured to, or operable to support a means for decoding the second set of bits in accordance with a second LDPC code defined by the base graph and a second lifting scheme, where the second lifting scheme is associated with probabilistic shaping.

Additionally, or alternatively, the communications manager 920 may support wireless communication in accordance with examples as disclosed herein. In some examples, the encoding component 925 is capable of, configured to, or operable to support a means for encoding a set of bits in accordance with a LDPC code associated with (for example, defined by) a base graph and a lifting scheme, where the base graph comprises a set of multiple variable nodes and a set of multiple check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes. In some examples, the transmission component 930 is capable of, configured to, or operable to support a means for transmitting a signal including the encoded set of bits.

Additionally, or alternatively, the communications manager 920 may support wireless communication in accordance with examples as disclosed herein. In some examples, the reception component 935 is capable of, configured to, or operable to support a means for receiving a signal including an encoded set of bits. In some examples, the decoding component 940 is capable of, configured to, or operable to support a means for decoding the encoded set of bits in accordance with a LDPC code associated with (for example, defined by) a base graph and a lifting scheme, where the base graph includes a set of multiple of variable nodes and a set of multiple of check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes.

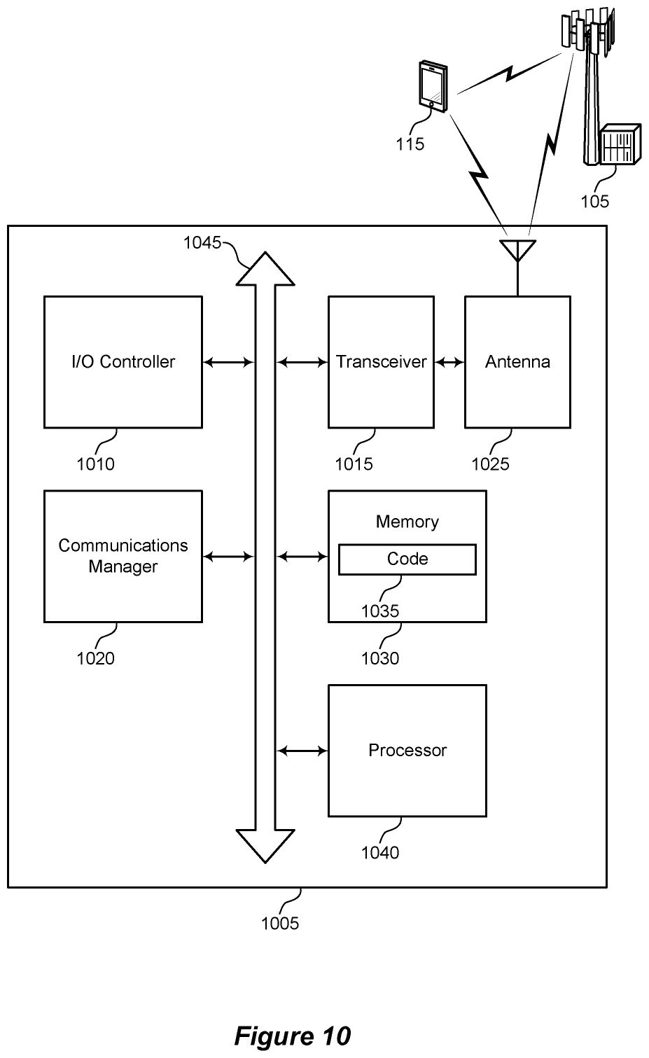

FIG. 10 shows a block diagram of an example system including a wireless communications device 1005 that supports lifting schemes for LDPC codes. The device 1005 may be an example of or include the components of a device 705, a device 805, or a UE 115 as described herein. The device 1005 may communicate (for example, wirelessly) with one or more network entities 105, one or more UEs 115, or any combination thereof. The device 1005 may include components for bi-directional voice and data communications including components for transmitting and receiving communications, such as a communications manager 1020, an input/output (I/O) controller 1010, a transceiver 1015, an antenna 1025, at least one memory 1030, code 1035, and at least one processor 1040. These components may be in electronic communication or otherwise coupled (for example, operatively, communicatively, functionally, electronically, electrically) via one or more buses (for example, a bus 1045).

The I/O controller 1010 may manage input and output signals for the device 1005. The I/O controller 1010 may also manage peripherals not integrated into the device 1005. In some cases, the I/O controller 1010 may represent a physical connection or port to an external peripheral. In some cases, the I/O controller 1010 may utilize an operating system such as iOS®, ANDROID®, MS-DOS®, MS-WINDOWS®, OS/2®, UNIX®, LINUX®, or another known operating system. Additionally or alternatively, the I/O controller 1010 may represent or interact with a modem, a keyboard, a mouse, a touchscreen, or a similar device. In some cases, the I/O controller 1010 may be implemented as part of one or more processors, such as the at least one processor 1040. In some cases, a user may interact with the device 1005 via the I/O controller 1010 or via hardware components controlled by the I/O controller 1010.

In some cases, the device 1005 may include a single antenna 1025. However, in some other cases, the device 1005 may have more than one antenna 1025, which may be capable of concurrently transmitting or receiving multiple wireless transmissions. The transceiver 1015 may communicate bi-directionally, via the one or more antennas 1025, wired, or wireless links as described herein. For example, the transceiver 1015 may represent a wireless transceiver and may communicate bi-directionally with another wireless transceiver. The transceiver 1015 may also include a modem to modulate the packets, to provide the modulated packets to one or more antennas 1025 for transmission, and to demodulate packets received from the one or more antennas 1025. The transceiver 1015, or the transceiver 1015 and one or more antennas 1025, may be an example of a transmitter 715, a transmitter 815, a receiver 710, a receiver 810, or any combination thereof or component thereof, as described herein.

The at least one memory 1030 may include random access memory (RAM) and read-only memory (ROM). The at least one memory 1030 may store computer-readable, computer-executable code 1035 including instructions that, when executed by the at least one processor 1040, cause the device 1005 to perform various functions described herein. The code 1035 may be stored in a non-transitory computer-readable medium such as system memory or another type of memory. In some cases, the code 1035 may not be directly executable by the at least one processor 1040 but may cause a computer (for example, when compiled and executed) to perform functions described herein. In some cases, the at least one memory 1030 may contain, among other things, a basic I/O system (BIOS) which may control basic hardware or software operation such as the interaction with peripheral components or devices.

The at least one processor 1040 may include an intelligent hardware device (for example, a general-purpose processor, a DSP, a CPU, a microcontroller, an ASIC, an FPGA, a programmable logic device, a discrete gate or transistor logic component, a discrete hardware component, or any combination thereof). In some cases, the at least one processor 1040 may be configured to operate a memory array using a memory controller. In some other cases, a memory controller may be integrated into the at least one processor 1040. The at least one processor 1040 may be configured to execute computer-readable instructions stored in a memory (for example, the at least one memory 1030) to cause the device 1005 to perform various functions (for example, functions or tasks supporting lifting schemes for LDPC codes). For example, the device 1005 or a component of the device 1005 may include at least one processor 1040 and at least one memory 1030 coupled with or to the at least one processor 1040, the at least one processor 1040 and at least one memory 1030 configured to perform various functions described herein. In some examples, the at least one processor 1040 may include multiple processors and the at least one memory 1030 may include multiple memories. One or more of the multiple processors may be coupled with one or more of the multiple memories, which may, individually or collectively, be configured to perform various functions herein.

The communications manager 1020 may support wireless communication in accordance with examples as disclosed herein. For example, the communications manager 1020 is capable of, configured to, or operable to support a means for encoding a set of bits in accordance with a LDPC code associated with (for example, defined by) a base graph and a lifting scheme, where the base graph includes a set of multiple check nodes and a set of multiple variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the set of bits, or a combination thereof. The communications manager 1020 is capable of, configured to, or operable to support a means for transmitting a signal including the encoded set of bits.

Additionally, or alternatively, the communications manager 1020 may support wireless communication in accordance with examples as disclosed herein. For example, the communications manager 1020 is capable of, configured to, or operable to support a means for receiving a signal including an encoded set of bits. The communications manager 1020 is capable of, configured to, or operable to support a means for decoding the encoded set of bits in accordance with a LDPC code associated with (for example, defined by) a base graph and a lifting scheme, where the base graph includes a set of multiple check nodes and a set of multiple variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the encoded set of bits, or a combination thereof.

Additionally, or alternatively, the communications manager 1020 may support wireless communication in accordance with examples as disclosed herein. For example, the communications manager 1020 is capable of, configured to, or operable to support a means for encoding a set of bits in accordance with a LDPC code associated with (for example, defined by) a base graph and a lifting scheme, where the base graph comprises a set of multiple variable nodes and a set of multiple check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes. The communications manager 1020 is capable of, configured to, or operable to support a means for transmitting a signal including the encoded set of bits.

Additionally, or alternatively, the communications manager 1020 may support wireless communication in accordance with examples as disclosed herein. For example, the communications manager 1020 is capable of, configured to, or operable to support a means for receiving a signal including an encoded set of bits. The communications manager 1020 is capable of, configured to, or operable to support a means for decoding the encoded set of bits in accordance with a LDPC code associated with (for example, defined by) a base graph and a lifting scheme, where the base graph includes a set of multiple of variable nodes and a set of multiple of check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes.

By including or configuring the communications manager 1020 in accordance with examples as described herein, the device 1005 may support techniques for increased throughput, reduced encoding and decoding complexity, reduced transmitter and receiver complexity, improved error floor performance, higher spectrum efficiency, reduced power consumption, longer battery life, and improved utilization of processing capability.

In some examples, the communications manager 1020 may be configured to perform various operations (for example, receiving, monitoring, transmitting) using or otherwise in cooperation with the transceiver 1015, the one or more antennas 1025, or any combination thereof. Although the communications manager 1020 is illustrated as a separate component, in some examples, one or more functions described with reference to the communications manager 1020 may be supported by or performed by the at least one processor 1040, the at least one memory 1030, the code 1035, or any combination thereof. For example, the code 1035 may include instructions executable by the at least one processor 1040 to cause the device 1005 to perform various aspects of lifting schemes for LDPC codes as described herein, or the at least one processor 1040 and the at least one memory 1030 may be otherwise configured to, individually or collectively, perform or support such operations.

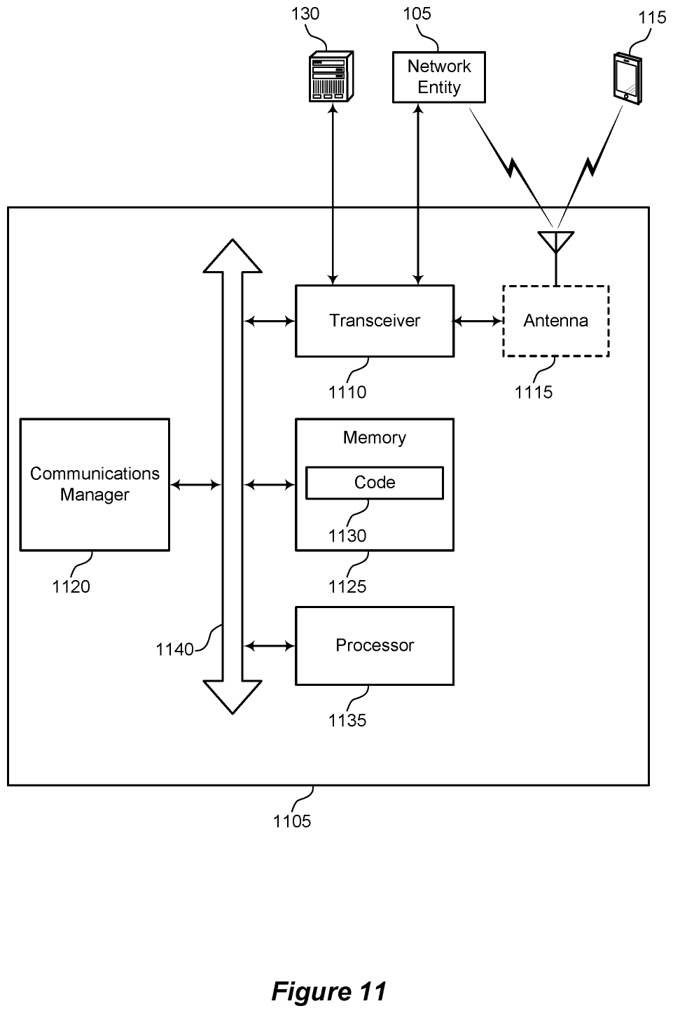

FIG. 11 shows a block diagram of an example system including a wireless communications device 1105 that supports lifting scheme for LDPC codes. The device 1105 may be an example of or include the components of a device 705, a device 805, or a network entity 105 as described herein. The device 1105 may communicate with one or more network entities 105, one or more UEs 115, or any combination thereof, which may include communications over one or more wired interfaces, over one or more wireless interfaces, or any combination thereof. The device 1105 may include components that support outputting and obtaining communications, such as a communications manager 1120, a transceiver 1110, an antenna 1115, at least one memory 1125, code 1130, and at least one processor 1135. These components may be in electronic communication or otherwise coupled (for example, operatively, communicatively, functionally, electronically, electrically) via one or more buses (for example, a bus 1140).

The transceiver 1110 may support bi-directional communications via wired links, wireless links, or both as described herein. In some examples, the transceiver 1110 may include a wired transceiver and may communicate bi-directionally with another wired transceiver. Additionally, or alternatively, in some examples, the transceiver 1110 may include a wireless transceiver and may communicate bi-directionally with another wireless transceiver. In some examples, the device 1105 may include one or more antennas 1115, which may be capable of transmitting or receiving wireless transmissions (for example, concurrently). The transceiver 1110 may also include a modem to modulate signals, to provide the modulated signals for transmission (for example, by one or more antennas 1115, by a wired transmitter), to receive modulated signals (for example, from one or more antennas 1115, from a wired receiver), and to demodulate signals. In some implementations, the transceiver 1110 may include one or more interfaces, such as one or more interfaces coupled with the one or more antennas 1115 that are configured to support various receiving or obtaining operations, or one or more interfaces coupled with the one or more antennas 1115 that are configured to support various transmitting or outputting operations, or a combination thereof. In some implementations, the transceiver 1110 may include or be configured for coupling with one or more processors or one or more memory components that are operable to perform or support operations based on received or obtained information or signals, or to generate information or other signals for transmission or other outputting, or any combination thereof. In some implementations, the transceiver 1110, or the transceiver 1110 and the one or more antennas 1115, or the transceiver 1110 and the one or more antennas 1115 and one or more processors or one or more memory components (for example, the at least one processor 1135, the at least one memory 1125, or both), may be included in a chip or chip assembly that is installed in the device 1105. In some examples, the transceiver 1110 may be operable to support communications via one or more communications links (for example, a communication link 125, a backhaul communication link 120, a midhaul communication link 162, a fronthaul communication link 168).

The at least one memory 1125 may include RAM, ROM, or any combination thereof. The at least one memory 1125 may store computer-readable, computer-executable code 1130 including instructions that, when executed by one or more of the at least one processor 1135, cause the device 1105 to perform various functions described herein. The code 1130 may be stored in a non-transitory computer-readable medium such as system memory or another type of memory. In some cases, the code 1130 may not be directly executable by a processor of the at least one processor 1135 but may cause a computer (for example, when compiled and executed) to perform functions described herein. In some cases, the at least one memory 1125 may contain, among other things, a BIOS which may control basic hardware or software operation such as the interaction with peripheral components or devices. In some examples, the at least one processor 1135 may include multiple processors and the at least one memory 1125 may include multiple memories. One or more of the multiple processors may be coupled with one or more of the multiple memories which may, individually or collectively, be configured to perform various functions herein (for example, as part of a processing system).

The at least one processor 1135 may include an intelligent hardware device (for example, a general-purpose processor, a DSP, an ASIC, a CPU, an FPGA, a microcontroller, a programmable logic device, discrete gate or transistor logic, a discrete hardware component, or any combination thereof). In some cases, the at least one processor 1135 may be configured to operate a memory array using a memory controller. In some other cases, a memory controller may be integrated into one or more of the at least one processor 1135. The at least one processor 1135 may be configured to execute computer-readable instructions stored in a memory (for example, one or more of the at least one memory 1125) to cause the device 1105 to perform various functions (for example, functions or tasks supporting lifting scheme for LDPC codes). For example, the device 1105 or a component of the device 1105 may include at least one processor 1135 and at least one memory 1125 coupled with one or more of the at least one processor 1135, the at least one processor 1135 and the at least one memory 1125 configured to perform various functions described herein. The at least one processor 1135 may be an example of a cloud-computing platform (for example, one or more physical nodes and supporting software such as operating systems, virtual machines, or container instances) that may host the functions (for example, by executing code 1130) to perform the functions of the device 1105. The at least one processor 1135 may be any one or more suitable processors capable of executing scripts or instructions of one or more software programs stored in the device 1105 (such as within one or more of the at least one memory 1125). In some implementations, the at least one processor 1135 may be a component of a processing system. A processing system may generally refer to a system or series of machines or components that receives inputs and processes the inputs to produce a set of outputs (which may be passed to other systems or components of, for example, the device 1105). For example, a processing system of the device 1105 may refer to a system including the various other components or subcomponents of the device 1105, such as the at least one processor 1135, or the transceiver 1110, or the communications manager 1120, or other components or combinations of components of the device 1105. The processing system of the device 1105 may interface with other components of the device 1105, and may process information received from other components (such as inputs or signals) or output information to other components. For example, a chip or modem of the device 1105 may include a processing system and one or more interfaces to output information, or to obtain information, or both. The one or more interfaces may be implemented as or otherwise include a first interface configured to output information and a second interface configured to obtain information, or a same interface configured to output information and to obtain information, among other implementations. In some implementations, the one or more interfaces may refer to an interface between the processing system of the chip or modem and a transmitter, such that the device 1105 may transmit information output from the chip or modem. Additionally, or alternatively, in some implementations, the one or more interfaces may refer to an interface between the processing system of the chip or modem and a receiver, such that the device 1105 may obtain information or signal inputs, and the information may be passed to the processing system. A person having ordinary skill in the art will readily recognize that a first interface also may obtain information or signal inputs, and a second interface also may output information or signal outputs.

In some examples, a bus 1140 may support communications of (for example, within) a protocol layer of a protocol stack. In some examples, a bus 1140 may support communications associated with a logical channel of a protocol stack (for example, between protocol layers of a protocol stack), which may include communications performed within a component of the device 1105, or between different components of the device 1105 that may be co-located or located in different locations (for example, where the device 1105 may refer to a system in which one or more of the communications manager 1020, the transceiver 1110, the at least one memory 1125, the code 1130, and the at least one processor 1135 may be located in one of the different components or divided between different components).

In some examples, the communications manager 1120 may manage aspects of communications with a core network 130 (for example, via one or more wired or wireless backhaul links). For example, the communications manager 1120 may manage the transfer of data communications for client devices, such as one or more UEs 115. In some examples, the communications manager 1120 may manage communications with other network entities 105, and may include a controller or scheduler for controlling communications with UEs 115 in cooperation with other network entities 105. In some examples, the communications manager 1120 may support an X2 interface within an LTE/LTE-A wireless communications network technology to provide communication between network entities 105.

The communications manager 1120 may support wireless communication in accordance with examples as disclosed herein. For example, the communications manager 1120 is capable of, configured to, or operable to support a means for encoding a set of bits in accordance with a LDPC code associated with (for example, defined by) a base graph and a lifting scheme, where the base graph includes a set of multiple check nodes and a set of multiple variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the set of bits, or a combination thereof. The communications manager 1120 is capable of, configured to, or operable to support a means for transmitting a signal including the encoded set of bits.

Additionally, or alternatively, the communications manager 1120 may support wireless communication in accordance with examples as disclosed herein. For example, the communications manager 1120 is capable of, configured to, or operable to support a means for receiving a signal including an encoded set of bits. The communications manager 1120 is capable of, configured to, or operable to support a means for decoding the encoded set of bits in accordance with a LDPC code associated with (for example, defined by) a base graph and a lifting scheme, where the base graph includes a set of multiple check nodes and a set of multiple variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the encoded set of bits, or a combination thereof.

Additionally, or alternatively, the communications manager 1120 may support wireless communication in accordance with examples as disclosed herein. For example, the communications manager 1120 is capable of, configured to, or operable to support a means for encoding a set of bits in accordance with a LDPC code associated with (for example, defined by) a base graph and a lifting scheme, where the base graph comprises a set of multiple variable nodes and a set of multiple check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes. The communications manager 1120 is capable of, configured to, or operable to support a means for transmitting a signal including the encoded set of bits.

Additionally, or alternatively, the communications manager 1120 may support wireless communication in accordance with examples as disclosed herein. For example, the communications manager 1120 is capable of, configured to, or operable to support a means for receiving a signal including an encoded set of bits. The communications manager 1120 is capable of, configured to, or operable to support a means for decoding the encoded set of bits in accordance with a LDPC code associated with (for example, defined by) a base graph and a lifting scheme, where the base graph includes a set of multiple of variable nodes and a set of multiple of check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes.

By including or configuring the communications manager 1120 in accordance with examples as described herein, the device 105 may support techniques for increased throughput, reduced encoding and decoding complexity, reduced transmitter and receiver complexity, improved error floor performance, higher spectrum efficiency, reduced power consumption, longer battery life, and improved utilization of processing capability.

In some examples, the communications manager 1120 may be configured to perform various operations (for example, receiving, obtaining, monitoring, outputting, transmitting) using or otherwise in cooperation with the transceiver 1110, the one or more antennas 1115 (for example, where applicable), or any combination thereof. Although the communications manager 1120 is illustrated as a separate component, in some examples, one or more functions described with reference to the communications manager 1120 may be supported by or performed by the transceiver 1110, one or more of the at least one processor 1135, one or more of the at least one memory 1125, the code 1130, or any combination thereof (for example, by a processing system including at least a portion of the at least one processor 1135, the at least one memory 1125, the code 1130, or any combination thereof). For example, the code 1130 may include instructions executable by one or more of the at least one processor 1135 to cause the device 1105 to perform various aspects of lifting scheme for LDPC codes as described herein, or the at least one processor 1135 and the at least one memory 1125 may be otherwise configured to, individually or collectively, perform or support such operations.

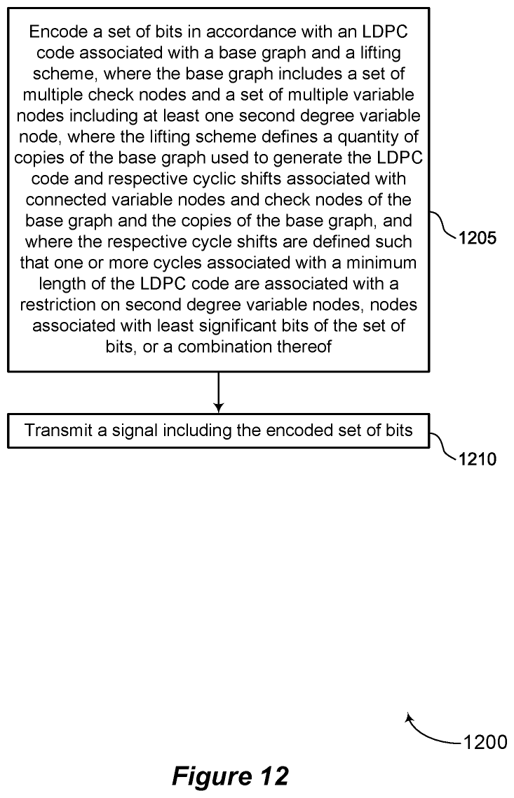

FIG. 12 shows a flowchart illustrating an example method 1200 that supports lifting schemes for LDPC codes. The operations of the method 1200 may be implemented by a UE or its components as described herein. For example, the operations of the method 1200 may be performed by a UE 115 as described with reference to FIGS. 1-11. In some examples, a UE may execute a set of instructions to control the functional elements of the UE to perform the described functions. Additionally, or alternatively, the UE may perform aspects of the described functions using special-purpose hardware.

At 1205, the method may include encoding a set of bits in accordance with a LDPC code associated with a base graph and a lifting scheme, where the base graph includes a set of multiple check nodes and a set of multiple variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the set of bits, or a combination thereof. The operations of block 1205 may be performed in accordance with examples as disclosed herein. In some examples, aspects of the operations of 1205 may be performed by an encoding component 925 as described with reference to FIG. 9.

At 1210, the method may include transmitting a signal including the encoded set of bits. The operations of block 1210 may be performed in accordance with examples as disclosed herein. In some examples, aspects of the operations of 1210 may be performed by a transmission component 930 as described with reference to FIG. 9.

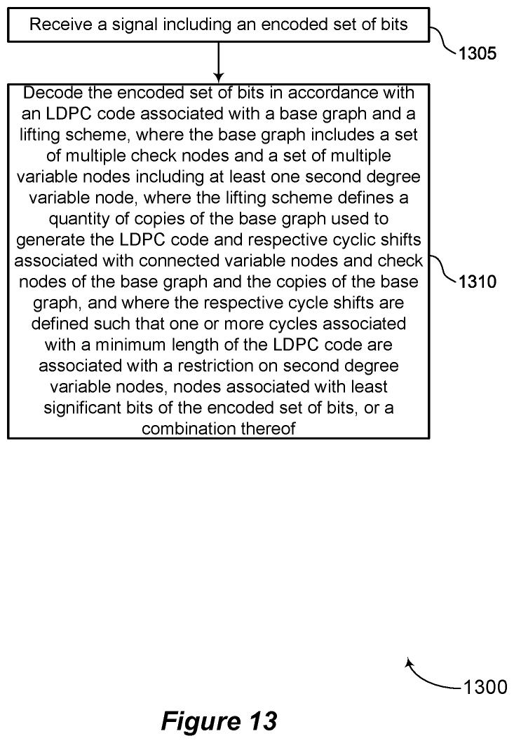

FIG. 13 shows a flowchart illustrating an example method 1300 that supports lifting schemes for LDPC codes. The operations of the method 1300 may be implemented by a UE or its components as described herein. For example, the operations of the method 1300 may be performed by a UE 115 as described with reference to FIGS. 1-11. In some examples, a UE may execute a set of instructions to control the functional elements of the UE to perform the described functions. Additionally, or alternatively, the UE may perform aspects of the described functions using special-purpose hardware.

At 1305, the method may include receiving a signal including an encoded set of bits. The operations of block 1305 may be performed in accordance with examples as disclosed herein. In some examples, aspects of the operations of 1305 may be performed by a reception component 935 as described with reference to FIG. 9.

At 1310, the method may include decoding the encoded set of bits in accordance with a LDPC code associated with a base graph and a lifting scheme, where the base graph includes a set of multiple check nodes and a set of multiple variable nodes including at least one second degree variable node, where the lifting scheme defines a quantity of copies of the base graph used to generate the LDPC code and respective cyclic shifts associated with connected variable nodes and check nodes of the base graph and the copies of the base graph, and where the respective cycle shifts are defined such that one or more cycles associated with a minimum length of the LDPC code are associated with a restriction on second degree variable nodes, nodes associated with least significant bits of the encoded set of bits, or a combination thereof. The operations of block 1310 may be performed in accordance with examples as disclosed herein. In some examples, aspects of the operations of 1310 may be performed by a decoding component 940 as described with reference to FIG. 9.

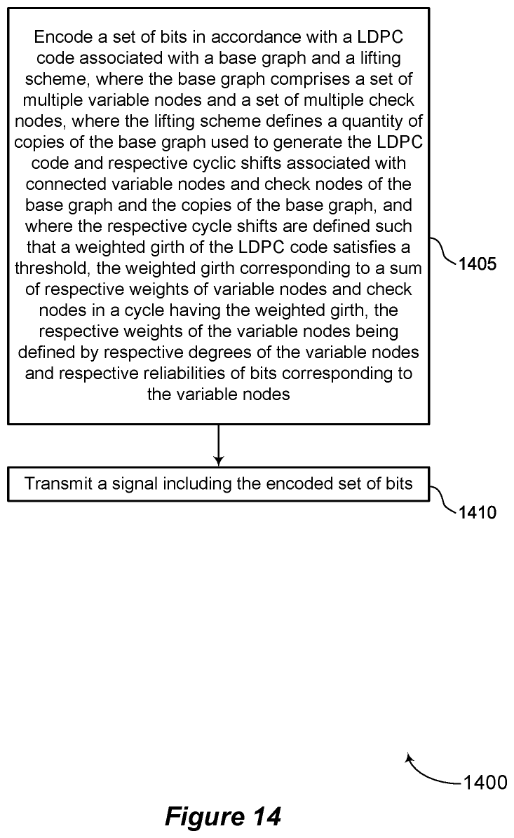

FIG. 14 shows a flowchart illustrating an example method 1400 that supports lifting schemes for LDPC codes. The operations of the method 1400 may be implemented by a UE or its components as described herein. For example, the operations of the method 1400 may be performed by a UE 115 as described with reference to FIGS. 1-11. In some examples, a UE may execute a set of instructions to control the functional elements of the UE to perform the described functions. Additionally, or alternatively, the UE may perform aspects of the described functions using special-purpose hardware.

At 1405, the method may include encoding a set of bits in accordance with a LDPC code associated with a base graph and a lifting scheme, where the base graph comprises a set of multiple variable nodes and a set of multiple check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes. The operations of block 1405 may be performed in accordance with examples as disclosed herein. In some examples, aspects of the operations of 1405 may be performed by an encoding component 925 as described with reference to FIG. 9.

At 1410, the method may include transmitting a signal including the encoded set of bits. The operations of block 1410 may be performed in accordance with examples as disclosed herein. In some examples, aspects of the operations of 1410 may be performed by a transmission component 930 as described with reference to FIG. 9.

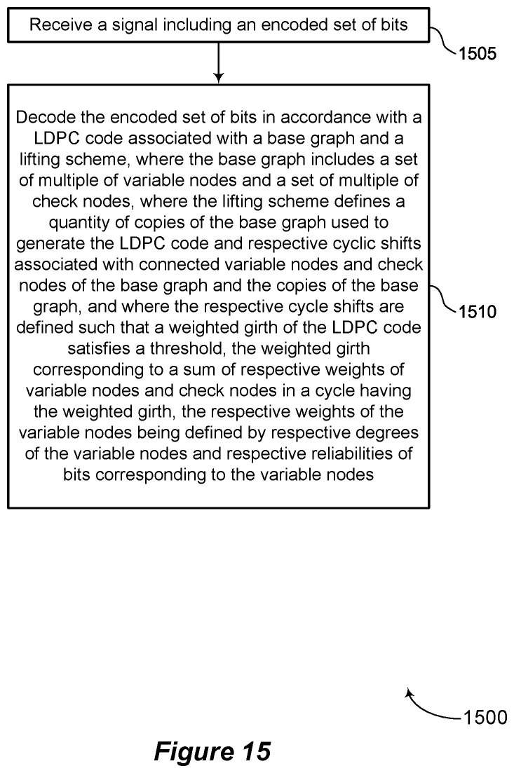

FIG. 15 shows a flowchart illustrating an example method 1500 that supports lifting schemes for LDPC codes. The operations of the method 1500 may be implemented by a UE or its components as described herein. For example, the operations of the method 1500 may be performed by a UE 115 as described with reference to FIGS. 1-11. In some examples, a UE may execute a set of instructions to control the functional elements of the UE to perform the described functions. Additionally, or alternatively, the UE may perform aspects of the described functions using special-purpose hardware.

At 1505, the method may include receiving a signal including an encoded set of bits. The operations of block 1505 may be performed in accordance with examples as disclosed herein. In some examples, aspects of the operations of 1505 may be performed by a reception component 935 as described with reference to FIG. 9.

At 1510, the method may include decoding the encoded set of bits in accordance with a LDPC code associated with a base graph and a lifting scheme, where the base graph includes a set of multiple of variable nodes and a set of multiple of check nodes, where the lifting scheme defines a quantity of copies of the base graph used to generate the LDPC code and respective cyclic shifts associated with connected variable nodes and check nodes of the base graph and the copies of the base graph, and where the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes. The operations of block 1510 may be performed in accordance with examples as disclosed herein. In some examples, aspects of the operations of 1510 may be performed by a decoding component 940 as described with reference to FIG. 9.

The following provides an overview of aspects of the present disclosure:

Aspect 1: A method for wireless communication by a transmitting device, comprising: encoding a set of bits in accordance with a LDPC code associated with a base graph and a lifting scheme, wherein the base graph comprises a plurality of check nodes and a plurality of variable nodes comprising at least one second degree variable node, wherein the lifting scheme defines a quantity of copies of the base graph used to generate the LDPC code and respective cyclic shifts associated with connected variable nodes and check nodes of the base graph and the copies of the base graph, and wherein the respective cycle shifts are defined such that one or more cycles associated with a minimum length of the LDPC code are associated with a restriction on second degree variable nodes, nodes associated with least significant bits of the set of bits, or a combination thereof; and transmitting a signal comprising the encoded set of bits.

Aspect 2: The method of aspect 1, wherein the second degree variable nodes are excluded from the one or more cycles associated with the minimum length in accordance with the restriction.

Aspect 3: The method of any of aspects 1 through 2, wherein the nodes associated with the least significant bits are excluded from the one or more cycles associated with the minimum length in accordance with the restriction.

Aspect 4: The method of any of aspects 1 and 3, wherein in accordance with the restriction, at least one third degree variable node is included in a cycle of the one or more cycles associated with the minimum length that includes at least one second degree variable node.

Aspect 5: The method of any of aspects 1 and 3 through 4, wherein in accordance with the restriction, a cycle of the one or more cycles associated with the minimum length excludes second degree variable nodes associated with the least significant bits and includes a second degree variable node associated with one or more bits of the set of bits that are more significant than the least significant bits.

Aspect 6: The method of any of aspects 1 through 5, wherein the minimum length corresponds to a length-six cycle.

Aspect 7: The method of any of aspects 1 through 6, wherein the respective cycle shifts are further defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes, respective reliabilities of bits corresponding to the variable nodes, or a combination thereof.

Aspect 8: The method of aspect 7, wherein a first weight of a first variable node is greater than a second weight of a second variable node in accordance with the first variable node being associated with a greater degree than the second variable node.

Aspect 9: The method of aspect 8, wherein the second variable node is associated with one or more bits that are more significant than one or more bits associated with the first variable node.

Aspect 10: The method of any of aspects 7 through 8, wherein a first weight of a first variable node is greater than a second weight of a second variable node in accordance with the first variable node being associated with a higher reliability than the second variable node.

Aspect 11: The method of any of aspects 7 through 8 and 10, wherein a first weight of a first variable node is greater than a second weight of a second variable node in accordance with the first variable node being associated with one or more bits that are more significant than one or more bits associated with the second variable node.

Aspect 12: The method of any of aspects 7 through 11, wherein the respective weights of the variable nodes are defined by whether the variable nodes correspond to punctured nodes of the base graph.

Aspect 13: The method of any of aspects 7 through 12, wherein the respective weights of the variable nodes are defined by the respective degrees of the variable nodes and the respective reliabilities in accordance with a modulation order associated with the set of bits satisfying a threshold order.

Aspect 14: The method of any of aspects 7 through 12, wherein the respective weights of the variable nodes are defined by the respective degrees of the variable nodes in accordance with a modulation order associated with the set of bits failing to satisfy a threshold order.

Aspect 15: The method of any of aspects 7 through 14, wherein a girth of the LDPC code fails to satisfy the threshold.

Aspect 16: The method of any of aspects 1 through 15, wherein the least significant bits of the set of bits are associated with a least reliable bit location of a modulation scheme for encoding the set of bits.

Aspect 17: The method of any of aspects 1 through 16, wherein the lifting scheme is associated with a first modulation scheme having a first modulation order, the method further comprising: encoding a second set of bits in accordance with a second LDPC code defined by the base graph and a second lifting scheme, wherein the second lifting scheme is associated with a second modulation scheme having a second modulation order; and transmitting a second signal comprising the encoded second set of bits.

Aspect 18: The method of aspect 17, further comprising: selecting the LDPC code to encode the set of bits in accordance with encoding the set of bits according to the first modulation scheme and the first modulation order satisfying a threshold; and selecting the second LDPC code to encode the second set of bits in accordance with encoding the second set of bits according to the second modulation scheme and the second modulation order failing to satisfy the threshold.

Aspect 19: The method of any of aspects 1 through 18, wherein the lifting scheme is associated with a uniform QAM scheme, the method further comprising: encoding a second set of bits in accordance with a second LDPC code defined by the base graph and a second lifting scheme, wherein the second lifting scheme is associated with probabilistic shaping; and transmitting a second signal comprising the encoded second set of bits.

Aspect 20: A method for wireless communication by a receiving device, comprising: receiving a signal comprising an encoded set of bits; and decoding the encoded set of bits in accordance with a LDPC code associated with a base graph and a lifting scheme, wherein the base graph comprises a plurality of check nodes and a plurality of variable nodes comprising at least one second degree variable node, wherein the lifting scheme defines a quantity of copies of the base graph used to generate the LDPC code and respective cyclic shifts associated with connected variable nodes and check nodes of the base graph and the copies of the base graph, and wherein the respective cycle shifts are defined such that one or more cycles associated with a minimum length of the LDPC code are associated with a restriction on second degree variable nodes, nodes associated with least significant bits of the encoded set of bits, or a combination thereof.

Aspect 21: The method of aspect 20, wherein the second degree variable nodes are excluded from the one or more cycles associated with the minimum length in accordance with the restriction.

Aspect 22: The method of any of aspects 20 through 21, wherein the nodes associated with the least significant bits are excluded from the one or more cycles associated with the minimum length in accordance with the restriction.

Aspect 23: The method of any of aspects 20 and 22, wherein in accordance with the restriction, at least one third degree variable node is included in a cycle of the one or more cycles associated with the minimum length that includes at least one second degree variable node.

Aspect 24: The method of any of aspects 20 and 22 through 23, wherein in accordance with the restriction, a cycle of the one or more cycles associated with the minimum length excludes second degree variable nodes associated with the least significant bits and includes a second degree variable node associated with one or more bits of the encoded set of bits that are more significant than the least significant bits.

Aspect 25: The method of any of aspects 20 through 24, wherein the minimum length corresponds to a length-six cycle.

Aspect 26: The method of any of aspects 20 through 25, wherein the respective cycle shifts are further defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes, respective reliabilities of bits corresponding to the variable nodes, or a combination thereof.

Aspect 27: The method of aspect 26, wherein a first weight of a first variable node is greater than a second weight of a second variable node in accordance with the first variable node being associated with a greater degree than the second variable node.

Aspect 28: The method of aspect 27, wherein the second variable node is associated with one or more bits that are more significant than one or more bits associated with the first variable node.

Aspect 29: The method of any of aspects 26 through 27, wherein a first weight of a first variable node is greater than a second weight of a second variable node in accordance with the first variable node being associated with a higher reliability than the second variable node.

Aspect 30: The method of any of aspects 26 through 27 and 29, wherein a first weight of a first variable node is greater than a second weight of a second variable node in accordance with the first variable node being associated with one or more bits that are more significant than one or more bits associated with the second variable node.

Aspect 31: The method of any of aspects 26 through 30, wherein the respective weights of the variable nodes are defined by whether the variable nodes correspond to punctured nodes of the base graph.

Aspect 32: The method of any of aspects 26 through 31, wherein the respective weights of the variable nodes are defined by the respective degrees of the variable nodes and the respective reliabilities in accordance with a modulation order associated with the encoded set of bits satisfying a threshold order.

Aspect 33: The method of any of aspects 26 through 31, wherein the respective weights of the variable nodes are defined by the respective degrees of the variable nodes in accordance with a modulation order associated with the set of bits failing to satisfy a threshold order.

Aspect 34: The method of any of aspects 26 through 33, wherein a girth of the LDPC code fails to satisfy the threshold.

Aspect 35: The method of any of aspects 20 through 34, wherein the least significant bits of the set of bits are associated with a least reliable bit location of a modulation scheme for encoding the set of bits.

Aspect 36: The method of any of aspects 20 through 35, wherein the lifting scheme is associated with a first modulation scheme having a first modulation order, the method further comprising: receiving a second signal comprising a second set of encoded bits; and decoding the second set of bits in accordance with a second LDPC code defined by the base graph and a second lifting scheme, wherein the second lifting scheme is associated with a second modulation scheme having a second modulation order.

Aspect 37: The method of aspect 36, further comprising: selecting the LDPC code to decode the set of bits in accordance with decoding the set of bits according to the first modulation scheme and the first modulation order satisfying a threshold; and selecting the second LDPC code to decode the second set of bits in accordance with decoding the second set of bits according to the second modulation scheme and the second modulation order failing to satisfy the threshold.

Aspect 38: The method of any of aspects 20 through 37, wherein the lifting scheme is associated with a uniform QAM scheme, the method further comprising: receiving a second signal comprising a second set of encoded bits; and decoding the second set of bits in accordance with a second LDPC code defined by the base graph and a second lifting scheme, wherein the second lifting scheme is associated with probabilistic shaping.

Aspect 39: A method for wireless communication by a transmitting device, comprising: encoding a set of bits in accordance with a LDPC code associated with a base graph and a lifting scheme, wherein the base graph comprises a plurality of variable nodes and a plurality of check nodes, wherein the lifting scheme defines a quantity of copies of the base graph used to generate the LDPC code and respective cyclic shifts associated with connected variable nodes and check nodes of the base graph and the copies of the base graph, and wherein the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes; and transmitting a signal comprising the encoded set of bits.

Aspect 40: A method for wireless communication by a receiving device, comprising: receiving a signal comprising an encoded set of bits; and decoding the encoded set of bits in accordance with a LDPC code associated with a base graph and a lifting scheme, wherein the base graph comprises a plurality of variable nodes and a plurality of check nodes, wherein the lifting scheme defines a quantity of copies of the base graph used to generate the LDPC code and respective cyclic shifts associated with connected variable nodes and check nodes of the base graph and the copies of the base graph, and wherein the respective cycle shifts are defined such that a weighted girth of the LDPC code satisfies a threshold, the weighted girth corresponding to a sum of respective weights of variable nodes and check nodes in a cycle having the weighted girth, the respective weights of the variable nodes being defined by respective degrees of the variable nodes and respective reliabilities of bits corresponding to the variable nodes.

Aspect 41: A transmitting device for wireless communication, comprising a processing system that includes processor circuitry and memory circuitry that stores code, the processing system configured to cause the transmitting device to perform a method of any of aspects 1 through 19.

Aspect 42: A transmitting device for wireless communication, comprising at least one means for performing a method of any of aspects 1 through 19.

Aspect 43: A non-transitory computer-readable medium storing code for wireless communication, the code comprising instructions executable by one or more processors to perform a method of any of aspects 1 through 19.

Aspect 44: A receiving device for wireless communication, comprising a processing system that includes processor circuitry and memory circuitry that stores code, the processing system configured to cause the receiving device to perform a method of any of aspects 20 through 38.

Aspect 45: A receiving device for wireless communication, comprising at least one means for performing a method of any of aspects 20 through 38.

Aspect 46: A non-transitory computer-readable medium storing code for wireless communication, the code comprising instructions executable by one or more processors to perform a method of any of aspects 20 through 38.

Aspect 47: A transmitting device for wireless communication, comprising a processing system that includes processor circuitry and memory circuitry that stores code, the processing system configured to cause the transmitting device to perform a method of aspect 39.

Aspect 48: A transmitting device for wireless communication, comprising at least one means for performing a method of aspect 39.

Aspect 49: A non-transitory computer-readable medium storing code for wireless communication, the code comprising instructions executable by one or more processors to perform a method of aspect 39.

Aspect 50: A receiving device for wireless communication, comprising a processing system that includes processor circuitry and memory circuitry that stores code, the processing system configured to cause the receiving device to perform a method of aspect 40.

Aspect 51: A receiving device for wireless communication, comprising at least one means for performing a method of aspect 40.

Aspect 52: A non-transitory computer-readable medium storing code for wireless communication, the code comprising instructions executable by one or more processors to perform a method of aspect 40.

It should be noted that the methods described herein describe possible implementations, and that the operations and the steps may be rearranged or otherwise modified and that other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (for example, a combination of a DSP and a microprocessor, multiple microprocessors, one or more microprocessors in conjunction with a DSP core, or any other such configuration). Any functions or operations described herein as being capable of being performed by a processor may be performed by multiple processors that, individually or collectively, are capable of performing the described functions or operations.

The functions described herein may be implemented using hardware, software executed by a processor, firmware, or any combination thereof. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk and Blu-ray disc. Disks may reproduce data magnetically, and discs may reproduce data optically using lasers. Combinations of the above are also included within the scope of computer-readable media. Any functions or operations described herein as being capable of being performed by a memory may be performed by multiple memories that, individually or collectively, are capable of performing the described functions or operations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

The term “determine” or “determining” encompasses a variety of actions and, therefore, “determining” can include calculating, computing, processing, deriving, investigating, looking up (such as via looking up in a table, a database or another data structure), ascertaining and the like. Also, “determining” can include receiving (for example, receiving information), accessing (for example, accessing data stored in memory) and the like. Also, “determining” can include resolving, obtaining, selecting, choosing, establishing, and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the appended drawings, describes example configurations and does not represent all the examples that may be implemented or that are within the scope of the claims. The term “example” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A transmitting device, comprising:
a processing system that includes processor circuitry and memory circuitry that stores code, the processing system configured to cause the transmitting device to:
encode a set of bits in accordance with a low-density parity-check code associated with a base graph and a lifting scheme, wherein the base graph comprises a plurality of check nodes and a plurality of variable nodes comprising at least one second degree variable node, wherein the lifting scheme defines a quantity of copies of the base graph used to generate the low-density parity-check code and respective cyclic shifts associated with connected variable nodes and check nodes of the base graph and the copies of the base graph, and wherein the respective cycle shifts are defined such that one or more cycles associated with a minimum length of the low-density parity-check code are associated with a restriction on second degree variable nodes, nodes associated with least significant bits of the set of bits, or a combination thereof; and
transmit a signal comprising the encoded set of bits.

2. The transmitting device of claim 1, wherein the second degree variable nodes are excluded from the one or more cycles associated with the minimum length in accordance with the restriction.

3. The transmitting device of claim 1, wherein the nodes associated with the least significant bits are excluded from the one or more cycles associated with the minimum length in accordance with the restriction.

4. The transmitting device of claim 1, wherein in accordance with the restriction, at least one third degree variable node is included in a cycle of the one or more cycles associated with the minimum length that includes at least one second degree variable node.

5. The transmitting device of claim 1, wherein in accordance with the restriction, a cycle of the one or more cycles associated with the minimum length excludes second degree variable nodes associated with the least significant bits and includes a second degree variable node associated with one or more bits of the set of bits that are more significant than the least significant bits.

6. The transmitting device of claim 1, wherein the minimum length corresponds to a length-six cycle.

7. The transmitting device of claim 1, wherein the respective cycle shifts are further defined such that a weighted girth of the low-density parity-check code satisfies a threshold, the weighted girth corresponding to a sum of respective weights of variable nodes and check nodes in a cycle having the weighted girth, the respective weights of the variable nodes being defined by respective degrees of the variable nodes, respective reliabilities of bits corresponding to the variable nodes, or a combination thereof.

8. The transmitting device of claim 7, wherein a first weight of a first variable node is greater than a second weight of a second variable node in accordance with the first variable node being associated with a greater degree than the second variable node.

9. The transmitting device of claim 8, wherein the second variable node is associated with one or more bits that are more significant than one or more bits associated with the first variable node.

10. The transmitting device of claim 7, wherein a first weight of a first variable node is greater than a second weight of a second variable node in accordance with the first variable node being associated with a higher reliability than the second variable node, one or more bits that are more significant than one or more bits associated with the second variable node, or any combination thereof.

11. The transmitting device of claim 7, wherein the respective weights of the variable nodes are defined by whether the variable nodes correspond to punctured nodes of the base graph.

12. The transmitting device of claim 7, wherein the respective weights of the variable nodes are defined by the respective degrees of the variable nodes and the respective reliabilities in accordance with a modulation order associated with the set of bits satisfying a threshold order.

13. The transmitting device of claim 7, wherein the respective weights of the variable nodes are defined by the respective degrees of the variable nodes in accordance with a modulation order associated with the set of bits failing to satisfy a threshold order.

14. The transmitting device of claim 7, wherein a girth of the low-density parity-check code fails to satisfy the threshold.

15. The transmitting device of claim 1, wherein the least significant bits of the set of bits are associated with a least reliable bit location of a modulation scheme for encoding the set of bits.

16. The transmitting device of claim 1, wherein the lifting scheme is associated with a first modulation scheme having a first modulation order, and the processing system is further configured to cause the transmitting device to:
encode a second set of bits in accordance with a second low-density parity-check code defined by the base graph and a second lifting scheme, wherein the second lifting scheme is associated with a second modulation scheme having a second modulation order; and
transmit a second signal comprising the encoded second set of bits.

17. The transmitting device of claim 16, wherein the processing system is further configured to cause the transmitting device to:
select the low-density parity-check code to encode the set of bits in accordance with encoding the set of bits according to the first modulation scheme and the first modulation order satisfying a threshold; and
select the second low-density parity-check code to encode the second set of bits in accordance with encoding the second set of bits according to the second modulation scheme and the second modulation order failing to satisfy the threshold.

18. The transmitting device of claim 1, wherein the lifting scheme is associated with a uniform quadrature amplitude modulation scheme, and the processing system is further configured to cause the transmitting device to:
encode a second set of bits in accordance with a second low-density parity-check code defined by the base graph and a second lifting scheme, wherein the second lifting scheme is associated with probabilistic shaping; and
transmit a second signal comprising the encoded second set of bits.

19. A receiving device, comprising:
a processing system that includes processor circuitry and memory circuitry that stores code, the processing system configured to cause the receiving device to:
receive a signal comprising an encoded set of bits; and
decode the encoded set of bits in accordance with a low-density parity-check code associated with a base graph and a lifting scheme, wherein the base graph comprises a plurality of check nodes and a plurality of variable nodes comprising at least one second degree variable node, wherein the lifting scheme defines a quantity of copies of the base graph used to generate the low-density parity-check code and respective cyclic shifts associated with connected variable nodes and check nodes of the base graph and the copies of the base graph, and wherein the respective cycle shifts are defined such that one or more cycles associated with a minimum length of the low-density parity-check code are associated with a restriction on second degree variable nodes, nodes associated with least significant bits of the encoded set of bits, or a combination thereof.

20. The receiving device of claim 19, wherein the second degree variable nodes are excluded from the one or more cycles associated with the minimum length in accordance with the restriction.

21. The receiving device of claim 19, wherein the nodes associated with the least significant bits are excluded from the one or more cycles associated with the minimum length in accordance with the restriction.

22. The receiving device of claim 19, wherein in accordance with the restriction, at least one third degree variable node is included in a cycle of the one or more cycles associated with the minimum length that includes at least one second degree variable node.

23. The receiving device of claim 19, wherein in accordance with the restriction, a cycle of the one or more cycles associated with the minimum length excludes second degree variable nodes associated with the least significant bits and includes a second degree variable node associated with one or more bits of the encoded set of bits that are more significant than the least significant bits.

24. The receiving device of claim 19, wherein the minimum length corresponds to a length-six cycle.

25. The receiving device of claim 19, wherein the respective cycle shifts are further defined such that a weighted girth of the low-density parity-check code satisfies a threshold, the weighted girth corresponding to a sum of respective weights of variable nodes and check nodes in a cycle having the weighted girth, the respective weights of the variable nodes being defined by respective degrees of the variable nodes, respective reliabilities of bits corresponding to the variable nodes, or a combination thereof.

26. The receiving device of claim 25, wherein a first weight of a first variable node is greater than a second weight of a second variable node in accordance with the first variable node being associated with a greater degree than the second variable node, a higher reliability than the second variable node, one or more bits that are more significant than one or more bits associated with the second variable node, or any combination thereof.

27. The receiving device of claim 25, wherein the respective weights of the variable nodes are defined by whether the variable nodes correspond to punctured nodes of the base graph.

28. The receiving device of claim 25, wherein the respective weights of the variable nodes are defined by the respective degrees of the variable nodes and the respective reliabilities in accordance with a modulation order associated with the encoded set of bits satisfying a threshold order.

29. A method for wireless communication by a transmitting device, comprising:
encoding a set of bits in accordance with a low-density parity-check code associated with a base graph and a lifting scheme, wherein the base graph comprises a plurality of check nodes and a plurality of variable nodes comprising at least one second degree variable node, wherein the lifting scheme defines a quantity of copies of the base graph used to generate the low-density parity-check code and respective cyclic shifts associated with connected variable nodes and check nodes of the base graph and the copies of the base graph, and wherein the respective cycle shifts are defined such that one or more cycles associated with a minimum length of the low-density parity-check code are associated with a restriction on second degree variable nodes, nodes associated with least significant bits of the set of bits, or a combination thereof; and
transmitting a signal comprising the encoded set of bits.

30. A method for wireless communication by a receiving device, comprising:
receiving a signal comprising an encoded set of bits; and
decoding the encoded set of bits in accordance with a low-density parity-check code associated with a base graph and a lifting scheme, wherein the base graph comprises a plurality of check nodes and a plurality of variable nodes comprising at least one second degree variable node, wherein the lifting scheme defines a quantity of copies of the base graph used to generate the low-density parity-check code and respective cyclic shifts associated with connected variable nodes and check nodes of the base graph and the copies of the base graph, and wherein the respective cycle shifts are defined such that one or more cycles associated with a minimum length of the low-density parity-check code are associated with a restriction on second degree variable nodes, nodes associated with least significant bits of the encoded set of bits, or a combination thereof.
